(19) United States
(12) Patent Application Publication
(10) Pub. No.: US 2026/0370238 A1
(43) Pub. Date: Nov. 19, 2026

(54) DECODER, ENCODER AND CORRESPONDING METHODS FOR DECODING A DIGITAL TIME-VARYING SIGNAL

(71) Applicant: Fraunhofer-Gesellschaft zur Förderung der angewandten Forschung e.V., München (DE)

(72) Inventors: Jonathan PFAFF, Berlin (DE); Heiner KIRCHHOFFER, Berlin (DE); Christian HELMRICH, Berlin (DE); Sophie PIENTKA, Berlin (DE); Christian RUDAT, Berlin (DE); Heiko SCHWARZ, Berlin (DE); Detlev MARPE, Berlin (DE); Thomas WIEGAND, Berlin (DE)

(73) Assignee: Fraunhofer-Gesellschaft zur Förderung der angewandten Forschung e.V., München (DE)

(21) Appl. No.: 19/738,512

(22) Filed: Jul. 12, 2026

Related U.S. Application Data
(63) Continuation of application No. PCT/EP2025/050705, filed on Jan. 13, 2025.

(30) Foreign Application Priority Data
Jan. 12, 2024 (EP) 24151739.0

(51) Int. Cl. H03M 7/40; H03M 7/30

(52) U.S. Cl. CPC H03M 7/4075; H03M 7/3073; H03M 7/6005; H03M 7/6011

(57) ABSTRACT

A decoder for decoding a digital time-varying signal from a data stream is presented. The decoder is configured to decode the digital time-varying signal by decoding each of sample-wise-entropy-coded temporal blocks of the temporal blocks by sequentially determining a predetermined sample value for sample positions of the respective sample-wise-entropy-coded temporal block by decoding a residual sample value for a current sample position, and correcting a prediction sample value for the current sample position using the residual sample value. The decoding the residual sample involves binary context-adaptively entropy decoding a first portion of a binarization of the residual sample value and decoding a remainder portion of the binarization, wherein the decoder is configured to derive a context for decoding at least one bin of the first portion using the predetermined sample value of one or more previous sample positions of the respective sample-wise-entropy-coded temporal block.

### CROSS-REFERENCE TO RELATED APPLICATIONS

This application is a continuation of copending International Application No. PCT/EP2025/050705, filed Jan. 13, 2025, which is incorporated herein by reference in its entirety, and additionally claims priority from European Application No. EP 24151739.0, filed Jan. 12, 2024, which is also incorporated herein by reference in its entirety.

Embodiment according to the invention relate to a decoder and an encoder for decoding a digital time-varying signal.

### BACKGROUND OF THE INVENTION

Digital time-varying signals are commonly used for representation of media and measurement data such as audio signals, biomedical signals, or seismic measurements. With the increase of signal generation, transportation and storage, there is demand for compression of such digital time-varying signals.

### SUMMARY

An embodiment may have a decoder for decoding a digital time-varying signal from a data stream, configured to decode the digital time-varying signal from the data stream in temporal blocks by decoding each of sample-wise-entropy-coded temporal blocks of the temporal blocks of the digital time-varying signal by sequentially determining a predetermined sample value for sample positions of the respective sample-wise-entropy-coded temporal block by decoding a residual sample value for a current sample position of the respective sample-wise-entropy-coded temporal block from the data stream, and correcting a prediction sample value for the current sample position using the residual sample value, wherein in the decoding the residual sample value for the current sample position of the respective sample-wise-entropy-coded temporal block involves binary context-adaptively entropy decoding a first portion of a binarization of the residual sample value and decoding a remainder portion of the binarization from the data stream, wherein the decoder is configured to derive a context for decoding at least one bin of the first portion using the predetermined sample value of one or more previous sample positions of the respective sample-wise-entropy-coded temporal block.

Another embodiment may have a decoder for decoding a digital time-varying signal from a data stream, configured to decode the digital time-varying signal from the data stream in temporal blocks by decoding each of coefficient-wise-entropy-coded temporal blocks of the temporal blocks of the digital time-varying signal by deriving, from the data stream, a predetermined rank indicating that, among transform coefficients of the coefficient-wise-entropy-coded temporal blocks, those transform coefficients having, along a scan order defined among the transform coefficients, a rank greater than the predetermined rank are zero, sequentially, reverse relative to the scan order, decoding the transform coefficients having a rank smaller than the predetermined rank, subjecting the transform coefficients of the respective coefficient-wise-entropy-coded temporal block to a re-transformation to obtain a time-domain residual signal, reconstructing the respective coefficient-wise-entropy-coded temporal block by correcting a prediction signal for the respective coefficient-wise-entropy-coded temporal block using the time-domain residual signal, wherein 1) the decoder is configured to derive the predetermined rank from the data stream by decoding a coarse rank index indexing one of several coarse rank positions along the scan order, and decoding a fine rank offset pointing to the predetermined rank relative to the one coarse rank position, and/or 2) the decoder is configured to, in the sequentially, reverse relative to the scan order, decoding the transform coefficients having a rank smaller than the predetermined rank, decode a currently decoded transform coefficient of the respective coefficient-wise-entropy-coded temporal block by binary context-adaptively entropy decoding a first portion of a binarization of the currently decoded transform coefficient and decoding a remainder portion of the binarization from the data stream, with deriving a context for decoding at least one bin of the first portion using one or more previously decoded transform coefficients of the respective coefficient-wise-entropy-coded temporal block.

Another embodiment may have an encoder for encoding a digital time-varying signal into a data stream, configured to encode the digital time-varying signal into the data stream in temporal blocks by encoding each of sample-wise-entropy-coded temporal blocks of the temporal blocks of the digital time-varying signal by sequentially determining predetermined sample value for sample positions of the respective sample-wise-entropy-coded temporal block by encoding a residual sample value for a current sample position of the respective sample-wise-entropy-coded temporal block into the data stream, the residual sample value being for correcting a prediction sample value for the current sample position using the residual sample value, wherein in the encoding the residual sample value for the current sample position of the respective sample-wise-entropy-coded temporal block involves binary context-adaptively entropy encoding a first portion of a binarization of the residual sample value and encoding a remainder portion of the binarization into the data stream, wherein the encoder is configured to derive a context for encoding at least one bin of the first portion using the predetermined sample value of one or more previous sample positions of the respective sample-wise-entropy-coded temporal block.

Another embodiment may have an encoder for encoding a digital time-varying signal into a data stream, configured to encode the digital time-varying signal into the data stream in temporal blocks by encoding each of coefficient-wise-entropy-coded temporal blocks of the temporal blocks of the digital time-varying signal by subjecting a time-domain residual signal of the respective coefficient-wise-entropy-coded temporal block, ought to allow for reconstructing the respective coefficient-wise-entropy-coded temporal block by correcting a prediction signal for the respective coefficient-wise-entropy-coded temporal block using the time-domain residual signal, to a transformation to obtain the transform coefficients, signaling in the data stream, a predetermined rank indicating that, among the transform coefficients of the coefficient-wise-entropy-coded temporal blocks, those transform coefficients having, along a scan order defined among the transform coefficients, a rank greater than the predetermined rank are zero, sequentially, reverse relative to the scan order, encoding the transform coefficients having a rank smaller than the predetermined rank, wherein 1) the encoder is configured to encode the predetermined rank into the data stream by encoding a coarse rank index indexing one of several coarse rank positions along the scan order, and encoding a fine rank offset pointing to the predetermined rank relative to the one coarse rank position, and/or 2) the encoder is configured to, in the sequentially, reverse relative to the scan order, encoding the transform coefficients having a rank smaller than the predetermined rank, encode a currently encoded transform coefficient of the respective coefficient-wise-entropy-coded temporal block by binary context-adaptively entropy encoding a first portion of a binarization of the currently decoded transform coefficient and encoding a remainder portion of the binarization into the data stream, with deriving a context for encoding at least one bin of the first portion using one or more previously encoded transform coefficients of the respective coefficient-wise-entropy-coded temporal block.

According to another embodiment, a method for decoding for decoding a digital time-varying signal from a data stream may have the steps of: decoding the digital time-varying signal from the data stream in temporal blocks by decoding each of sample-wise-entropy-coded temporal blocks of the temporal blocks of the digital time-varying signal by sequentially determining a predetermined sample value for sample positions of the respective sample-wise-entropy-coded temporal block by decoding a residual sample value for a current sample position of the respective sample-wise-entropy-coded temporal block from the data stream, and correcting a prediction sample value for the current sample position using the residual sample value, wherein in the decoding the residual sample value for the current sample position of the respective sample-wise-entropy-coded temporal block involves binary context-adaptively entropy decoding a first portion of a binarization of the residual sample value and decoding a remainder portion of the binarization from the data stream, wherein the method includes deriving a context for decoding at least one bin of the first portion using the predetermined sample value of one or more previous sample positions of the respective sample-wise-entropy-coded temporal block.

According to another embodiment, a method for decoding a digital time-varying signal from a data stream may have the steps of: decoding the digital time-varying signal from the data stream in temporal blocks by decoding each of coefficient-wise-entropy-coded temporal blocks of the temporal blocks of the digital time-varying signal by deriving, from the data stream, a predetermined rank indicating that, among transform coefficients of the coefficient-wise-entropy-coded temporal blocks, those transform coefficients having, along a scan order defined among the transform coefficients, a rank greater than the predetermined rank are zero, sequentially, reverse relative to the scan order, decoding the transform coefficients having a rank smaller than the predetermined rank, subjecting the transform coefficients of the respective coefficient-wise-entropy-coded temporal block to a re-transformation to obtain a time-domain residual signal, reconstructing the respective coefficient-wise-entropy-coded temporal block by correcting a prediction signal for the respective coefficient-wise-entropy-coded temporal block using the time-domain residual signal, wherein 1) the method includes s deriving the predetermined rank from the data stream by decoding a coarse rank index indexing one of several coarse rank positions along the scan order, and decoding a fine rank offset pointing to the predetermined rank relative to the one coarse rank position, and/or 2) the includes, in the sequentially, reverse relative to the scan order, decoding the transform coefficients having a rank smaller than the predetermined rank, decoding a currently decoded transform coefficient of the respective coefficient-wise-entropy-coded temporal block by binary context-adaptively entropy decoding a first portion of a binarization of the currently decoded transform coefficient and decoding a remainder portion of the binarization from the data stream, with deriving a context for decoding at least one bin of the first portion using one or more previously decoded transform coefficients of the respective coefficient-wise-entropy-coded temporal block.

According to another embodiment, a method for encoding a digital time-varying signal into a data stream may have the steps of: encoding the digital time-varying signal into the data stream in temporal blocks by encoding each of sample-wise-entropy-coded temporal blocks of the temporal blocks of the digital time-varying signal by sequentially determining predetermined sample value for sample positions of the respective sample-wise-entropy-coded temporal block by encoding a residual sample value for a current sample position of the respective sample-wise-entropy-coded temporal block into the data stream, the residual sample value being for correcting a prediction sample value for the current sample position using the residual sample value, wherein in the encoding the residual sample value for the current sample position of the respective sample-wise-entropy-coded temporal block involves binary context-adaptively entropy encoding a first portion of a binarization of the residual sample value and encoding a remainder portion of the binarization into the data stream, wherein the method includes deriving a context for encoding at least one bin of the first portion using the predetermined sample value of one or more previous sample positions of the respective sample-wise-entropy-coded temporal block.

According to another embodiment, a method for encoding a digital time-varying signal into a data stream may have the steps of: encoding the digital time-varying signal into the data stream in temporal blocks by encoding each of coefficient-wise-entropy-coded temporal blocks of the temporal blocks of the digital time-varying signal by subjecting a time-domain residual signal of the respective coefficient-wise-entropy-coded temporal block, ought to allow for reconstructing the respective coefficient-wise-entropy-coded temporal block by correcting a prediction signal for the respective coefficient-wise-entropy-coded temporal block using the time-domain residual signal, to a transformation to obtain the transform coefficients, signaling in the data stream, a predetermined rank indicating that, among the transform coefficients of the coefficient-wise-entropy-coded temporal blocks, those transform coefficients having, along a scan order defined among the transform coefficients, a rank greater than the predetermined rank are zero, sequentially, reverse relative to the scan order, encoding the transform coefficients having a rank smaller than the predetermined rank, wherein 1) the method includes encoding the predetermined rank into the data stream by encoding a coarse rank index indexing one of several coarse rank positions along the scan order, and encoding a fine rank offset pointing to the predetermined rank relative to the one coarse rank position, and/or 2) the method includes, in the sequentially, reverse relative to the scan order, encoding the transform coefficients having a rank smaller than the predetermined rank, encoding a currently encoded transform coefficient of the respective coefficient-wise-entropy-coded temporal block by binary context-adaptively entropy encoding a first portion of a binarization of the currently decoded transform coefficient and encoding a remainder portion of the binarization into the data stream, with deriving a context for encoding at least one bin of the first portion using one or more previously encoded transform coefficients of the respective coefficient-wise-entropy-coded temporal block.

Another embodiment may have a data stream encoded using the first inventive method for encoding.

Another embodiment may have a data stream encoded using the second inventive method for encoding.

Another embodiment may have a non-transitory digital storage medium having a computer program stored thereon to perform any of the inventive methods when said computer program is run by a computer.

In accordance with a first aspect of the present invention, a decoder for decoding a digital time-varying signal from a data stream is provided. The decoder is configured to decode the digital time-varying signal from the data stream in temporal blocks by decoding each of sample-wise-entropy-coded temporal blocks of the temporal blocks of the digital time-varying signal by sequentially determining a predetermined sample value for sample positions of the respective sample-wise-entropy-coded temporal block by decoding a residual sample value for a current sample position of the respective sample-wise-entropy-coded temporal block from the data stream, and correcting a prediction sample value for the current sample position using the residual sample value, wherein in the decoding the residual sample value for the current sample position of the respective sample-wise-entropy-coded temporal block involves binary context-adaptively entropy decoding a first portion of a binarization of the residual sample value and decoding a remainder portion of the binarization from the data stream, wherein the decoder is configured to derive a context for decoding at least one bin of the first portion using the predetermined sample value of one or more previous sample positions of the respective sample-wise-entropy-coded temporal block.

Digital time-varying signals commonly have structures with redundancies over time (and/or inter-channel redundancies) that can be reduced by using a prediction sample value that is subsequently corrected using the residual sample value. It has been recognized that such residual sample values often have value distributions with high prevalence of low values. Such value distributions can benefit from providing residual sample value in form of the first and second portion of binarizations. The first portion of the binarization can be coded so as to adapt to frequently occurring low values. Since the temporal blocks are sample-wise-entropy-coded, a previously coded sample can be available for decoding of a currently coded sample. Such a previously coded sample has a higher probability of having a similar value and therefore a suitable indicator for context selection. However, particularly advantageous is a context derivation for the first portion of the binarization, which can be used to code a general size of the predetermined sample value (e.g., with the second portion usable to define the final value more accurately). By deriving the context for decoding at least one bin of the first portion allows obtaining a context that may be decently representative of the value of the value to be decoded, using the fact that sample-wise coding allows access to previously coded samples of the same block.

According to a second aspect, a decoder for decoding a digital time-varying signal from a data stream is provided. The decoder is configured to decode the digital time-varying signal from the data stream in temporal blocks by decoding each of coefficient-wise-entropy-coded temporal blocks of the temporal blocks of the digital time-varying signal by deriving, from the data stream, a predetermined rank indicating that, among transform coefficients of the coefficient-wise-entropy-coded temporal blocks, those transform coefficients having, along a scan order defined among the transform coefficients, a rank greater than the predetermined rank are zero, sequentially, reverse relative to the scan order, decoding the transform coefficients having a rank smaller than the predetermined rank, subjecting the transform coefficients of the respective coefficient-wise-entropy-coded temporal block to a re-transformation to obtain a time-domain residual signal, reconstructing the respective coefficient-wise-entropy-coded temporal block by correcting a prediction signal for the respective coefficient-wise-entropy-coded temporal block using the time-domain residual signal. The decoder is configured to derive the predetermined rank from the data stream by decoding a coarse rank index indexing one of several coarse rank positions along the scan order, and decoding a fine rank offset pointing to the predetermined rank relative to the one coarse rank position, and/or 2) decoder is configured to, in the sequentially, reverse relative to the scan order, decoding the transform coefficients having a rank smaller than the predetermined rank, decode a currently decoded transform coefficient of the respective coefficient-wise-entropy-coded temporal block by binary context-adaptively entropy decoding a first portion of a binarization of the currently decoded transform coefficient and decoding a remainder portion of the binarization from the data stream, with deriving a context for decoding at least one bin of the first portion using one or more previously decoded transform coefficients of the respective coefficient-wise-entropy-coded temporal block.

The coefficient-wide-entropy-coded temporal blocks are usually not decodable by sample. However, the coefficients often follow a value distribution that results in lower coefficients or even zero-coefficients towards the end of the scan order. Providing the predetermined rank therefore allows inferring, which coefficients are zero and don't have to be actively transmitted/decoded. Deriving the predetermined rank using a coarse rank index and a fin rank, allows transmission and decoding the rank with low complexity and high compression. The coefficients commonly tend to follow a trend along the scan order, which means the previously coded transform coefficients may be indicative of a currently coded transform coefficient, which allows improving coding efficiency by deriving a context for the first portion using previously coded transform coefficients.

According to an aspect, corresponding encoders for encoding a digital time-varying signal into a data stream are provided.

According a further aspect, corresponding methods for decoding and encoding a digital time-varying signal into a data stream are provided.

An embodiment is related to a data stream having a digital-time varying signal (e.g., an audio signal, biometric signal, or seismic signal) encoded thereinto using a herein described method for encoding. The data stream may be stored on a storage medium (e.g., non-transitory storage medium).

An embodiment is related to a computer program (e.g., stored on a storage medium, e.g., non-transitory storage medium, e.g., computer program product) having a program code for performing, when running on a computer, a herein described method, when being executed on the computer.

### BRIEF DESCRIPTION OF THE DRAWINGS

Embodiments of the present invention will be detailed subsequently referring to the appended drawings, in which:

FIG. 1 shows a schematic view of a decoder for decoding a digital time-varying signal from a data stream;

FIG. 2 shows a schematic view of another example of an encoder;

FIG. 3 shows a schematic view of an encoder for encoding a digital time-varying signal into a data stream;

FIG. 4 shows a schematic view of another example of the encoder;

FIG. 5 shows a schematic view of a first variation of another example of a decoder for decoding a digital time-varying signal from a data stream;

FIG. 6 shows a schematic view of a second variation of another example of a decoder for decoding a digital time-varying signal from a data stream;

FIG. 7 shows a schematic view of a first variation of another example of an encoder for encoding a digital time-varying signal into a data stream;

FIG. 8 shows a schematic view of a second variation of another example of an encoder for encoding a digital time-varying signal into a data stream; and

FIG. 9 which shows an encoder for encoding a multi-channel digital signal into a datastream as well as decoder for decoding the multi-channel digital signal from datastream.

### DETAILED DESCRIPTION OF THE INVENTION

Equal or equivalent elements or elements with equal or equivalent functionality are denoted in the following description by equal or equivalent reference numerals even if occurring in different figures.

In the following description, a plurality of details is set forth to provide a more throughout explanation of embodiments of the present invention. However, it will be apparent to those skilled in the art that embodiments of the present invention may be practiced without these specific details. In other instances, well-known structures and devices are shown in block diagram form rather than in detail in order to avoid obscuring embodiments of the present invention. In addition, features of the different embodiments described herein after may be combined with each other, unless specifically noted otherwise.

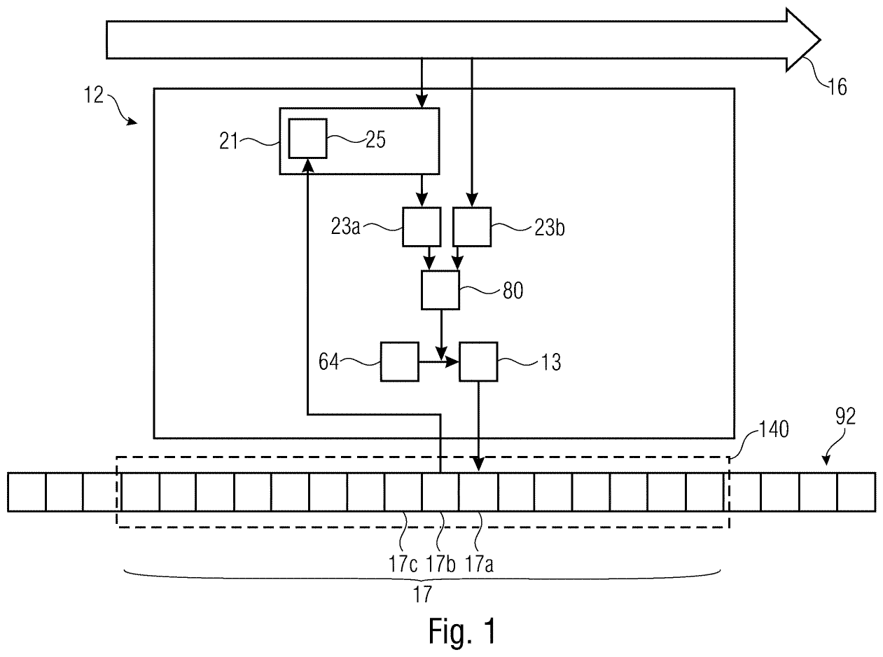

FIG. 1 shows a schematic view of a decoder 12 for decoding a digital time-varying signal 92 from a data stream 16. The decoder 12 may be configured to decode a data stream 16 encoded by any encoder disclosed herein. The decoder 12 may comprise any feature in any combination of any other decoder disclosed herein.

The decoder 12 is configured to decode the digital time-varying signal 92 from the data stream 16 in temporal blocks 140 by decoding each of sample-wise-entropy-coded temporal blocks of the temporal blocks 140 of the digital time-varying signal 92 by sequentially (e.g. using a sample order leading from older to newer sample positions, e.g., in a temporal order of the digital time-varying signal 92) determining a predetermined sample value 13 (e.g. the reconstructed sample value or just a residual sample value relative to a first-order-prediction, e.g., a first sample value, determined by an encoder) for sample positions (e.g., sixteen sample positions as shown in FIG. 1 or any other number of sample positions) of the respective sample-wise-entropy-coded temporal block 140 by decoding a residual sample value 80 (e.g., in form of or comprised by a residual signal) for a current sample position 17a of the respective sample-wise-entropy-coded temporal block 140 from the data stream 16, and correcting a prediction sample value 64 (e.g., in form of or comprised by a prediction signal) for the current sample position 17a using the residual sample value 80.

The decoding the residual sample value 80 for the current sample position 17a of the respective sample-wise-entropy-coded temporal block 140 involves binary context-adaptively entropy decoding 21 a first portion 23a of a binarization of the residual sample value 80 and decoding a remainder portion 23b of the binarization from the data stream 16.

The decoder 12 is configured to derive a context 25 (e.g., one or more contexts, e.g., contexts for different portions and/or bins, e.g., a context for one bin and another context for another bin) for decoding at least one bin of the first portion 23a using a predetermined sample value (e.g. a reconstructed sample value or just a residual sample value relative to a first-order-prediction, e.g., a second sample values) of one or more previous sample positions 17b, 17c of the respective sample-wise-entropy-coded temporal block 140.

The digital time-varying signal 92 may comprise one or more channels. Alternatively, the digital time-varying signal 92 may be part of (e.g., in form of one or more channels) of an overall digital time-varying signal. A channel may define a single parameter assuming values over time, e.g., wherein the parameter is sampled over temporally successive samples. The time digital time-varying signal 92 may comprise or be an audio signal (e.g., having one or more audio channels), a biomedical signal (e.g., an electrogram such as obtained by electroencephalography, electrocardiogram, or electrooculography), or a seismic signal. Any decoder 12 disclosed herein may be a decoder 12 for decoding an audiosignal, a biomedical signal, or a seismic signal. Any encoder 10 disclosed herein be an encoder for encoding an audiosignal, a biomedical signal, or a seismic signal. The digital time-varying signal 92 may be or comprise one or more waveform signals. Any disclosure related herein to examples with a single channel may also be applicable in any combination to digital time-varying signal 92 having multiple channels.

Samples (which may each define a single sample value) may be arranged along a temporal order in a time domain. A sample-wise coding may comprise completing reconstruction (which may be lossy or lossless) of a previous sample a before coding a next sample. In other words, while coding a current sample, a reconstruction of an immediately preceding sample may be completed, allowing said immediately preceding sample to be available for the coding of the current sample.

A temporal blocks 140 may form a linear array of samples. The plurality of temporal blocks 140 may have a same (or different) block length (or number of samples). For example, a temporal block 140 may comprise 16, 32, 64, 128, 256, 512, or 1024 samples (or any other number, e.g., different from a power of two). A sample position may define a temporal position within a temporal block 140. For example, a temporal block 140 may comprise sixteen samples, which occupying sample positions one to 16 (in temporal order).

The predetermined sample value 13 of a sample may be a (e.g., completely) reconstructed version of the sample or an intermediate value obtained during reconstruction. The predetermined sample value 13 may be a reconstructed sample value or just a residual sample value relative to a first-order-prediction.

Correcting the prediction sample value 64 for the current sample position 17a using the residual sample value 80 may comprise (or be realized by) a linear combination (e.g., a sum or a weighted sum) of the prediction sample value 64 and the residual sample value 80.

The residual sample value 80 may comprise or may consist of first portion 23a and the remainder portion 23b. The residual sample 80 may be formed by or based on a concatenation of the first portion 23a and the remainder portion 23b. The remainder portion 23b may or may not be decoded in a manner different from binary context-adaptively entropy decoding. The one or more previous sample positions 17b, 17c of the respective sample-wise-entropy-coded temporal block 140 (for context derivation) may be immediately precede (temporally) the current sample position 17a (or, alternatively, skip one or more sample positions towards the current sample position 17a). The one or more previous sample positions 17b, 17c may be exclusive of the same temporal block 140 as the current sample position 17a (e.g., all previous sample positions within the same temporal block 140 preceding the current sample position 17a, e.g., up to a maximum amount of sample positions). The number of previous sample positions 17b, 17c may be identical for the decoding of different sample positions. The number of previous sample positions 17b, 17c may have a lower and/or upper threshold.

A context may be derived for multiple bins (or all bins) of the first portion 23a, wherein each context may be derived based on the predetermined sample value of the same or different one or more previous sample positions 17b, 17c. The context of a bin of the first portion 23a may be derived based on one or more already decoded bins of the first portion 23a (e.g., in addition to the predetermined sample value of the one or more previous sample positions 17b, 17c). The context may define a set of symbols (e.g., code book or alphabet) for coding the one or more bins.

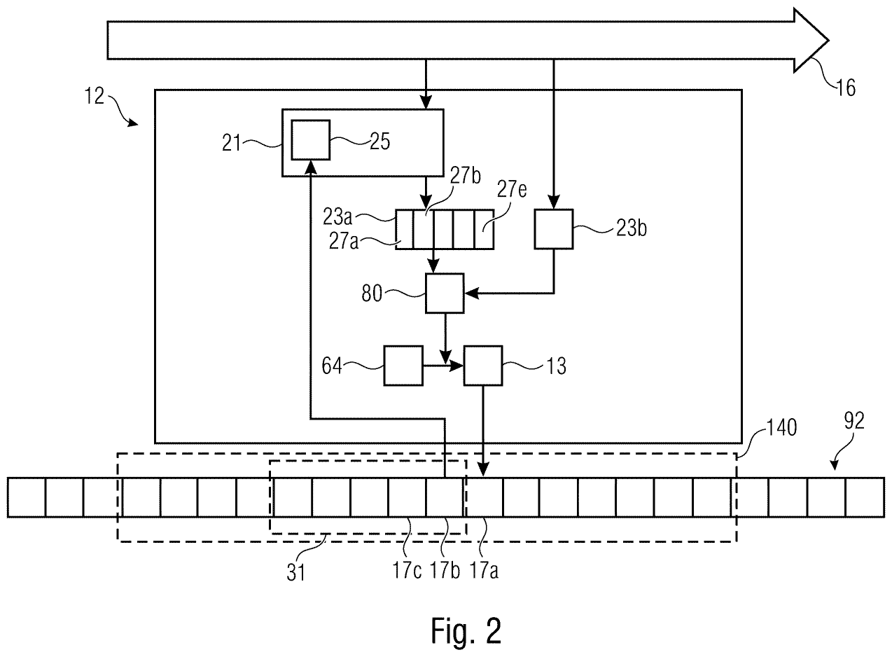

FIG. 2 shows a schematic view of another example of an encoder 12. Any feature disclosed with reference to FIG. 2 may be used in any combination of features in any decoder 12 disclosed herein.

The decoder 12 may be configured to derive a first context for decoding a first predetermined bin 27a (which may optionally be a first bin to be coded within the bin sequence) of the first portion 23a using a sum (which may optionally be weighted) of absolute values of the predetermined sample value of preceding sample positions 17b, c of the respective sample-wise-entropy-coded temporal block 140 positioned within a template 31 having a predetermined relative temporal position (e.g., the template defining an amount and/or spatial distance relative to the current sample position) relative to the current sample position and use the context for entropy decoding the at least one bin, and/or a zeroness and/or a sign of the predetermined sample value of an immediately preceding sample position of the respective sample-wise-entropy-coded temporal block. For example, the first context may derived based on whether the predetermined sample value of an immediately preceding sample position is equal to zero, less than zero or larger than zero (e.g., having three possible states, e.g., having two possible states, for example, in case of deriving dependent only on the sign of value of the preceding sample value). Alternatively or additionally, the first context may be derived based on the sum of absolute values within the template 31 (e.g., within the temporal block 140). The template 31 shown in FIG. 2 comprises (or consists of) five immediately preceding sample positions. However, any other amount of sample positions in any other spatial distance may be used instead. Furthermore, the amount of sample positions may be fixed or vary (e.g., in order to use only sample positions within the temporal block 140).

The first predetermined bin 27a may be a significance flag indicative of the residual sample 80 value being zero or not.

The decoder 12 may be configured to derive a second context for decoding a sequence of greater-bins 27b-e (e.g., flag) of the first portion 23a, each of which being indicative of whether the residual sample value 80 is greater than x+const with x being a rank of the respective greater-bin (e.g. and const being a constant such as zero, e.g., a constant larger than zero), depending on one or more of x−1 (or x−1 clipped to a first maximum value, e.g., an amount of greaterX_flags decoded so far, e.g., a value X of the greaterX_flag reduced by one, which may optionally be clipped to a first maximum value), and a sum of absolute values of the predetermined sample value of preceding sample positions of the respective sample-wise-entropy-coded temporal block positioned within a template 31 having the predetermined relative temporal position relative to the current sample position 17a and use the context for entropy decoding the at least one bin 27b, or a quantized and clipped version of the sum. For example, the first portion 23a may comprise a greater-than-one bin 27b, a greater-than-two bin 27c, a greater-than-three bin 27d, and a greater-than-four bin 27e. However, any other amount of greater-bins 27b-e indicating being greater than any other number (and optionally with a constant) may be used. For example, a second context for decoding a greater-than-two bin 27c may be derived depending one at least one of a greater-than-one bin 27b and a sum (which may optionally be clipped and/or quantized) of absolute values of the predetermined sample value of preceding sample positions of the respective sample-wise-entropy-coded temporal block positioned within a template 31.

The decoder 12 may be configured to derive the prediction sample value 64 for the current sample position 17a using a template 31 of K sample positions (e.g., with K=5 in FIG. 2, but any other number may be used for K, e.g., any power of two) immediately preceding the current sample position 17a along a (e.g., temporal) sample order along which the predetermined sample value for the sample positions of the respective sample-wise-entropy-coded temporal block 140 are sequentially decoded, by forming a weighted sum of the predetermined sample value of the respective sample-wise-entropy-coded temporal block at the K sample positions.

The decoder 12 may be configured to derive a second context for decoding a sequence of greater-bins 27b-e of the first portion 23a, each of which being indicative of whether the residual sample value is greater than x+const with x being a rank of the respective greater-bin, depending on one or more of x−1, x−1 clipped to a first maximum value, and whether the current sample position 17a is, reverse to the sample order (e.g., in FIG. 2 in a distance measured from the sample position 17a towards the left), distanced by less than K sample positions from a previously decoded temporal block (e.g., wherein the last three sample positions of the previous block are depicted to the left of temporal block 140). In other words, the second context for decoding a sequence of greater-bins 27b-e may depend on whether the current sample position 17a is arranged within the temporal block 140 at a position smaller than K.

The decoder 12 may be configured to, in decoding the remainder portion 23b of the binarization from the data stream 16 determine a Rice parameter (e.g., a parameter determining a division of the value of the current sample position) by quantizing or thresholding an absolute sum measure over the predetermined sample value of all preceding sample positions of the respective sample-wise-entropy-coded temporal block 140, and decode a Rice code using the Rice parameter. The Rice code may comprise a unary code quotient portion (e.g., a remainder after a division based on the Rice parameter), and the decoder 12 may be configured to decode bins of the unary code quotient portion by means of context-adaptive binary entropy decoding.

The unary code quotient portion may be a truncated unary code truncated so that a number of codewords of the truncated unary code is limited to a predefined maximal quotient value and wherein, if the unary code portion of the Rice code assumes a predetermined codeword associated with the predefined maximal quotient value, a fixed length remainder portion of the Rice coding may be absent and the decoder 12 may be configured to, if the unary code portion of the Rice code does not assume the predetermined codeword associated with the predefined maximal quotient value, decode the fixed length remainder portion having a length corresponding to the Rice parameter. The decoder 12 may be configured to, if the unary code portion of the Rice code assumes the predetermined codeword associated with the predefined maximal quotient value, decode an exponential Golomb code as an extension of the Rice code.

The decoder 12 may be configured to, in decoding each of sample-wise-entropy-coded temporal blocks of the temporal blocks 140 of the digital time-varying signal 92, predict the respective sample-wise-entropy-coded temporal blocks of the temporal blocks 140 using a selected one out of a set of prediction modes to obtain a prediction signal 64 (e.g., wherein the prediction signal 64 may comprise a prediction sample value 64 of one, a subset or all samples of the temporal block 140), and correcting, at each of the sample positions 17 of the respective sample-wise-entropy-coded temporal block 140, the prediction signal 64 using the predetermined sample value (e.g. the reconstructed sample value or just a residual sample value relative to a first-order-prediction) for the respective sample position of the respective sample-wise-entropy-coded temporal block.

The set of prediction modes may comprise one or more of an intra prediction mode (which mode may also be called block-copy mode), an inter-prediction mode (which mode may also be called cross-channel prediction mode, e.g., in case of the digital time-varying signal 92 comprising more than one channel), a mixed prediction mode, a DC prediction mode, and any other mode disclosed herein.

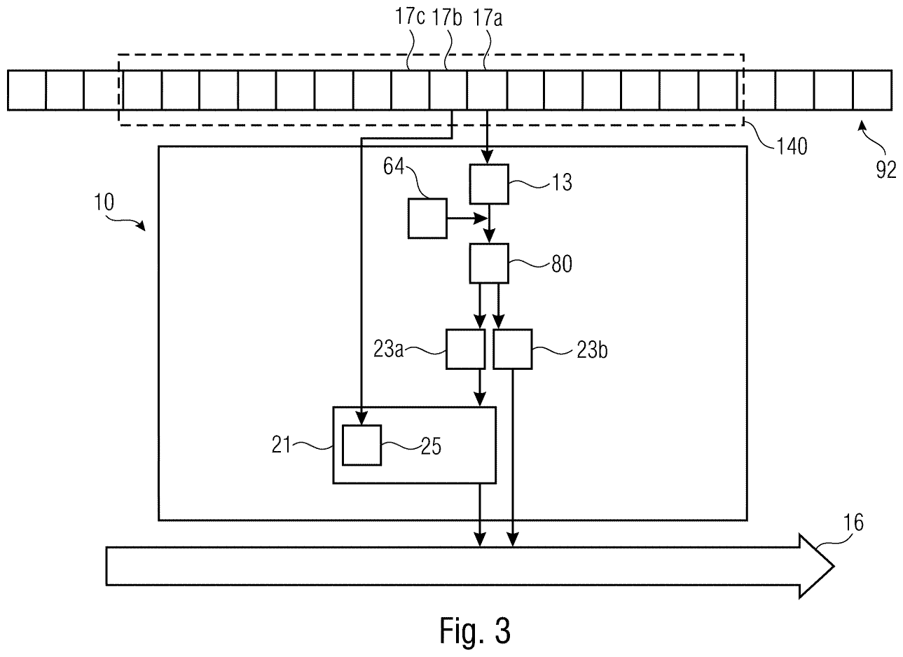

FIG. 3 shows a schematic view of an encoder 10 for encoding a digital time-varying signal 92 into a data stream 16. The encoder 10 may be configured to encode a data stream 16 decodable by any decoder disclosed herein. The encoder 10 may comprise any feature in any combination of any other encoder disclosed herein. Any decoder-side feature disclosed herein by be applied to any encoder disclosed herein.

The encoder 10 is configured to encode the digital time-varying signal 92 into the data stream 16 in temporal blocks 140 by encoding each of sample-wise-entropy-coded temporal blocks of the temporal blocks 140 of the digital time-varying signal 92 by sequentially (e.g. using a sample order leading from older to newer sample positions) determining pre-determined sample value 13 (e.g. the reconstructed sample value or just a residual sample value relative to a first-order-prediction) for sample positions 17 of the respective sample-wise-entropy-coded temporal block 140 by encoding a residual sample value 80 for a current sample position 17a of the respective sample-wise-entropy-coded temporal block 140 into the data stream 16, the residual sample value 80 being for correcting a prediction sample value 64 for the current sample position 17a using the residual sample value 80.

The encoding the residual sample value 80 for the current sample position 17a of the respective sample-wise-entropy-coded temporal block 140 involves binary context-adaptively entropy encoding a first portion 23a of a binarization of the residual sample value 80 and encoding a remainder portion 23b of the binarization into the data stream 16.

The encoder 10 is configured to derive a context 25 for encoding at least one bin of the first portion 23a using the predetermined sample value of one or more previous sample positions 17b, 17c of the respective sample-wise-entropy-coded temporal block 140.

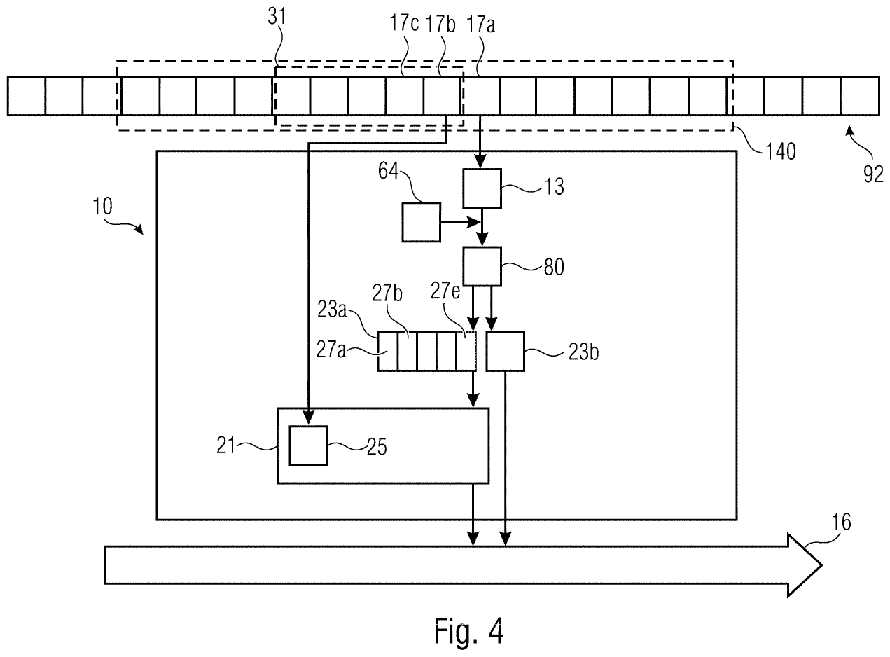

FIG. 4 shows a schematic view of another example of the encoder 10. Any feature disclosed with reference to FIG. 4 may be used in any combination of features in any encoder disclosed herein.

The encoder 10 of may be configured to derive a first context for encoding a first predetermined bin 27a of the first portion 23a using a sum (which may optionally be weighted) of absolute values of the predetermined sample value of preceding sample positions 17b, c of the respective sample-wise-entropy-coded temporal block 140 positioned within a template 31 having a predetermined relative temporal position relative to the current sample position and may use the context for entropy encoding the at least one bin 27a, and/or a zeroness and/or a sign of the predetermined sample value of an immediately preceding sample position of the respective sample-wise-entropy-coded temporal block.

The first predetermined bin 27a may be a significance flag indicative of the residual sample value 80 being zero or not.

The encoder may be configured to derive a second context for encoding a sequence of greater-bins 27b-e (e.g., one or more of bins 27b-e) of the first portion 23a, each of which being indicative of whether the residual sample value 80 is greater than x+const with x being a rank of the respective greater-bin (e.g. and const being a constant such as zero), depending one or more of x−1, x−1 clipped to a first maximum value, and a sum of absolute values of the predetermined sample value of preceding sample positions of the respective sample-wise-entropy-coded temporal block positioned within a template having the predetermined relative temporal position relative to the current sample position and use the context for entropy encoding the at least one bin, or a quantized and clipped version of the sum (e.g., dependent on a quantized and/or clipped version of the sum).

The encoder 10 may be configured to derive the prediction sample value 64 for the current sample position 17a using a template 31 of K sample (e.g., with K=5 in FIG. 2, but any other number may be used for K) positions 27b, c immediately preceding the current sample position 27a along a sample order along which the predetermined sample value for the sample positions of the respective sample-wise-entropy-coded temporal block 140 are sequentially encoded, by forming a weighted sum of the predetermined sample value of the respective sample-wise-entropy-coded temporal block at the K sample positions.

The encoder 10 may be configured to derive a second context for encoding a sequence of greater-bins 27b-e (e.g., one or more of bins 27b-e) of the first portion 23a, each of which being indicative of whether the residual sample value is greater than x+const with x being a rank of the respective greater-bin, depending on one or more of x−1 (or x−1 clipped to a first maximum value), and whether the current sample position 17a is, reverse to the sample order, distanced by less than K sample positions from a previously encoded temporal block.

The encoder 10 may be configured to, in encoding the remainder portion 23b of the binarization into the data stream 16, determine a Rice parameter by quantizing or thresholding an absolute sum measure over the predetermined sample value of all preceding sample positions of the respective sample-wise-entropy-coded temporal block 140, and encode a Rice code using the Rice parameter. The Rice code may comprise a unary code quotient portion, and the encoder 10 may be configured to encode bins of the unary code quotient portion by means of context-adaptive binary entropy encoding. The unary code quotient portion may be a truncated unary code truncated so that a number of codewords of the truncated unary code is limited to a predefined maximal quotient value and wherein, if the unary code portion of the Rice code assumes a predetermined codeword associated with the predefined maximal quotient value, a fixed length remainder portion of the Rice coding may be absent and the encoder 10 may be configured to, if the unary code portion of the Rice code does not assume the predetermined codeword associated with the predefined maximal quotient value, encode the fixed length remainder portion having a length corresponding to the Rice parameter. The encoder 10 may be configured to, if the unary code portion of the Rice code assumes the predetermined codeword associated with the predefined maximal quotient value, encode an exponential Golomb code as an extension of the Rice code.

The encoder 10 may be configured to, in encoding each of sample-wise-entropy-coded temporal blocks of the temporal blocks 140 of the digital time-varying signal 92, predict the respective sample-wise-entropy-coded temporal blocks of the temporal blocks 140 using a selected one out of a set of prediction modes to obtain a prediction signal 64, so that, at each of the sample positions of the respective sample-wise-entropy-coded temporal block 140, the prediction signal 64 is correctable using the predetermined sample value (e.g. the reconstructed sample value or just a residual sample value relative to a first-order-prediction) for the respective sample position of the respective sample-wise-entropy-coded temporal block 140.

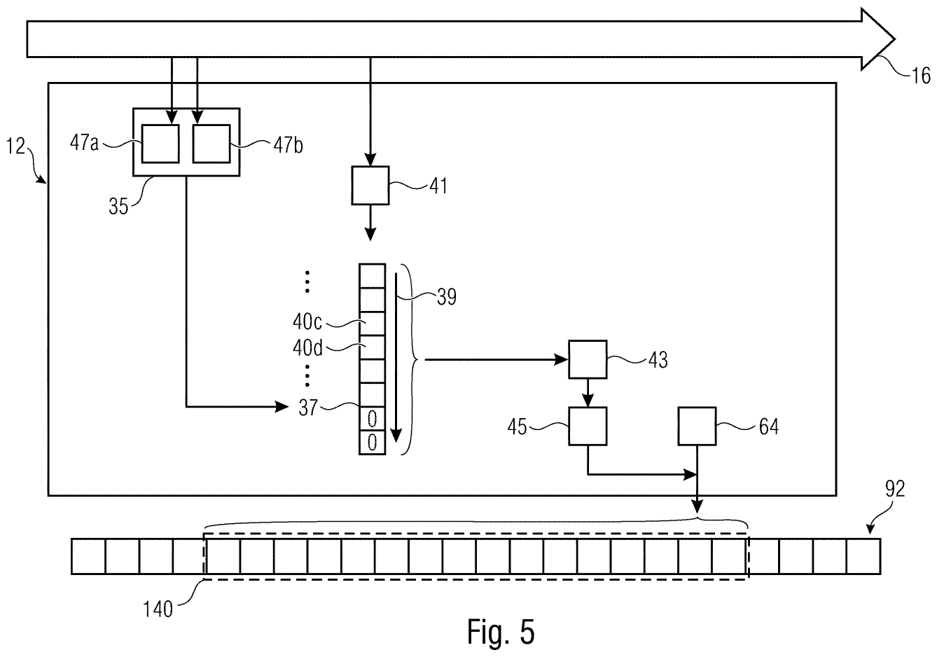

FIG. 5 shows a schematic view of a first variation of another example of a decoder 12 for decoding a digital time-varying signal 92 from a data stream 16.

The decoder 12 is configured to decode the digital time-varying signal 92 from the data stream 16 in temporal blocks by decoding each of coefficient-wise-entropy-coded temporal blocks of the temporal blocks 140 of the digital time-varying signal 92 by deriving 35, from the data stream 16, a predetermined rank 37 indicating that, among transform coefficients 40 (e.g., samples in a transform domain) of the coefficient-wise-entropy-coded temporal blocks, those transform coefficients 40 having, along a scan order 39 defined among the transform coefficients 40, a rank greater than the predetermined rank 37 are zero, sequentially, reverse relative to the scan order 39 (e.g., in FIG. 5 from the bottom to the top), decoding 41 (e.g., at least, e.g., only) the transform coefficients 40 having a rank smaller than the predetermined rank 37 (e.g., smaller than or equal to the rank of the predetermined rank 37, e.g., all the non-zero coefficients), and subjecting 43 the transform coefficients of the respective coefficient-wise-entropy-coded temporal block to a re-transformation to obtain a time-domain residual signal 45 (e.g., comprising one or more time-domain residual signals 13), reconstructing the respective coefficient-wise-entropy-coded temporal block 140 by correcting a prediction signal 64 for the respective coefficient-wise-entropy-coded temporal block using the time-domain residual signal 45.

It is noted that the predetermined rank 37 may indicate a rank between (in scan order 39) two transform coefficients (e.g., instead of ranks associated with transform coefficients 40), e.g., between (along scan order 39) a last non-zero coefficient and a first zero-coefficient. In such case all non-zero coefficients may have a rank smaller than the predetermined rank 37 and the zero-coefficients may have a rank greater than the predetermined rank 37 (e.g., with no transform coefficient having a rank equal to the predetermined rank 37). In a different embodiment, the predetermined rank 37 may indicate a rank of transform coefficients 40, in which case, the predetermined rank 37 may indicate the rank of the last transform coefficient (in scan order 39) that has a non-zero value (e.g., the last non-zero coefficient may have a rank equal to the predetermined rank 37). The decoder 12 may be configured to decode at least the transform coefficients 40 having a rank smaller than the predetermined rank 37 and may further decode the transform coefficient 40 having a rank equal to the predetermined rank 37. In a further different embodiment, the predetermined rank 37 may indicate those transform coefficients 40 having (along a scan order 39) a rank greater than and equal to the predetermined rank 37 are zero. The decoder 12 may be configured to (only) decode the transform coefficients 40 having a rank smaller than the predetermined rank 37 and not transform coefficients 40 having a rank equal to the predetermined rank 37. In either case, the predetermined rank 37 allows distinguishing non-zero-coefficients from zero-coefficients (e.g., enables identifying non-zero-coefficients based on the predetermined rank 37). As a result, non-zero-coefficients can be decoded.

According to a first variation (e.g., as shown in FIG. 5), the decoder 12 is configured to derive 35 the predetermined rank 37 from the data stream 16 by decoding a coarse rank index 47a indexing one of several coarse rank positions along the scan order 39, and decoding a fine rank offset 47b pointing to the predetermined rank 37 relative to the one coarse rank position. The coarse rank positions may be arranged at equal distances from each other, such as a distance of four (e.g., with three positions between two coarse rank positions). In other words, the coarse rank positions may subdivide the block of transform coefficients into subblocks, wherein, for example the coarse rank index indexes the subblock that comprises the predetermined rank (e.g., with the corase rank position indicating a start or end of a subblock).

The decoder 12 may be configured to derive the predetermined rank 37 from the data stream 16 by decoding the fine rank offset 47b using a fixed length code (e.g. where all bins are bypass coded by the underlying CABAC engine, e.g., where the probability 0.5 is assumed for the value of all these bins). The decoder 12 may be configured to decode the fixed length code into the data stream at a code rate (e.g., of a forward error correction code) of 1.

The decoder 12 may be configured to derive the predetermined rank 37 from the data stream 16 by decoding the coarse rank index 47a using a truncated unary code if the one coarse rank position falls onto one of X (e.g., with X being a number such as two, three, four, or higher, e.g., a power of two) leading coarse rank positions in scan order 39 (e.g., an amount of X coarse rank positions that are arranged at the earliest positions along the scan order 39, e.g., wherein the X coarse rank positions separated by more than one rank position), and using the truncated unary code for X followed by a truncated binary code for indexing the one coarse rank position out of subsequent coarse rank positions following the X leading coarse rank positions in scan order 39, if the one coarse rank position does not fall onto the X leading coarse rank positions in scan order. In other words, an optional truncated binary code may additionally be used for indexing the one coarse rank position, if the one coarse rank position does not fall onto the X leading coarse rank positions (e.g., does not fall onto early rank positions).

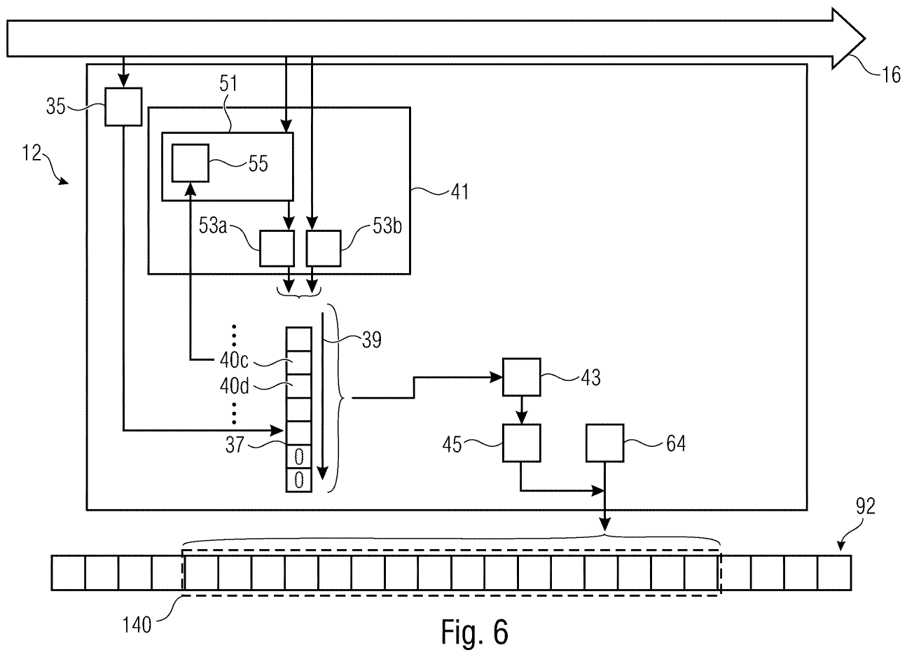

FIG. 6 shows a schematic view of a second variation of another example of a decoder 12 for decoding a digital time-varying signal 92 from a data stream 16.

Similar, as shown before in FIG. 5, the decoder 12 is configured to decode the digital time-varying signal 92 from the data stream 16 in temporal blocks by decoding each of coefficient-wise-entropy-coded temporal blocks of the temporal blocks 140 of the digital time-varying signal 92 by deriving 35, from the data stream 16, a predetermined rank 37 indicating that, among transform coefficients 40 (e.g., samples in a transform domain) of the coefficient-wise-entropy-coded temporal blocks, those transform coefficients 40 having, along a scan order 39 defined among the transform coefficients 40, a rank greater than the predetermined rank are zero, sequentially, reverse relative to the scan order 39, decoding 41 the transform coefficients 40 (e.g., FIG. 6 shows eight transform coefficients, wherein the last two coefficients have a value of zero and an exemplary transform coefficient 40d is a currently decoded transform coefficient) having a rank smaller than the predetermined rank 37 (e.g., smaller than or equal to the rank of the predetermined rank 37, e.g., all the non-zero coefficients), and subjecting 43 the transform coefficients of the respective coefficient-wise-entropy-coded temporal block to a re-transformation to obtain a time-domain residual signal 45, reconstructing the respective coefficient-wise-entropy-coded temporal block 140 by correcting a prediction signal 64 for the respective coefficient-wise-entropy-coded temporal block using the time-domain residual signal 45.

According to the second variation, the decoder 12 is configured to, in the sequentially, reverse relative to the scan order 39, decoding the transform coefficients 40 having a rank smaller than the predetermined rank 37 (e.g., smaller than or equal to the rank of the predetermined rank 37, e.g., all the non-zero coefficients), decode a currently decoded transform coefficient 40d (in FIG. 6, the currently decoded transform coefficient is exemplarily indicated with reference sigh 40d, but any other transform coefficient may be the currently decoded transform coefficient) of the respective coefficient-wise-entropy-coded temporal block by binary context-adaptively entropy decoding 51 a first portion 53a of a binarization of the currently decoded transform coefficient 40d and decoding a remainder portion 53b of the binarization from the data stream 16, with deriving a context 55 for decoding at least one bin of the first portion 53a using one or more previously decoded transform coefficients of the respective coefficient-wise-entropy-coded temporal block.

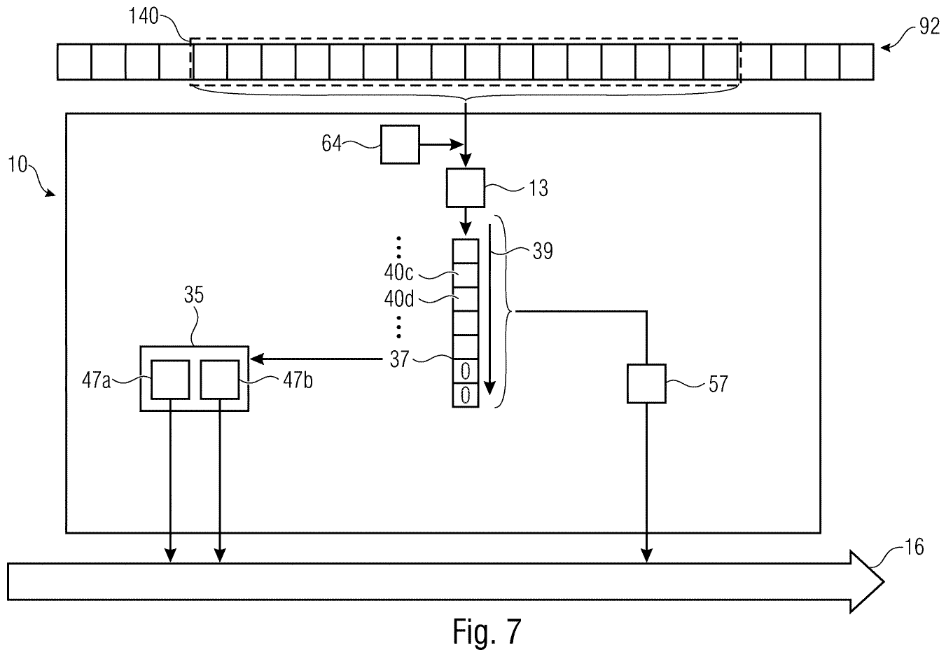

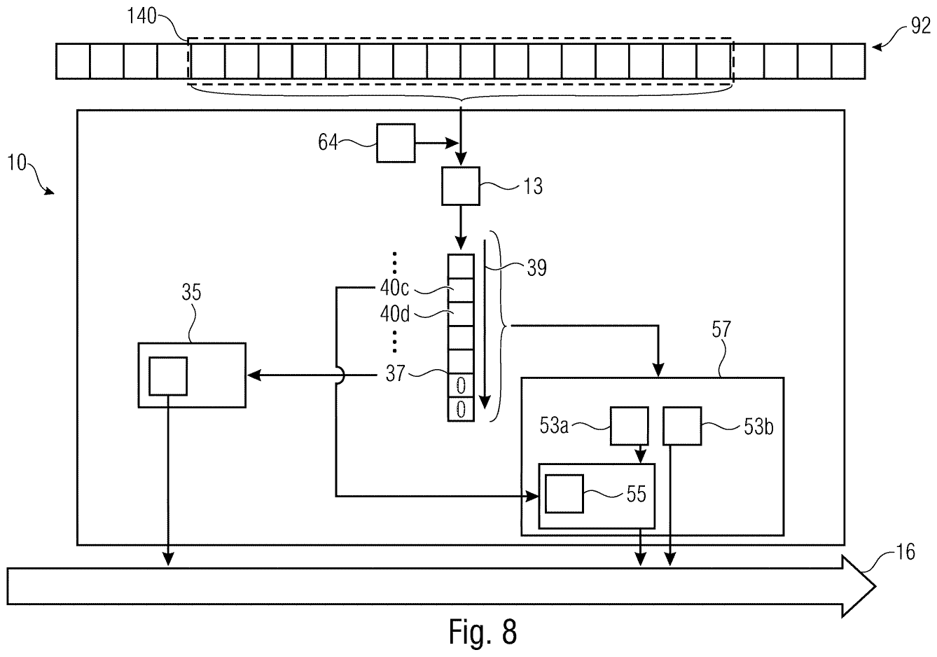

It is noted that the examples described with reference to FIG. 5 und 6 are merely termed “variations”, for emphasizing that coding two portions of a value (e.g., coarse rank index 47a and fine rank offset 47b as well as a first portion 53a and a remainder portion 53b) can be used for different value types, such as a rank position and a transform coefficient. However, the two variations are not exclusive to each other. For example, the predetermined rank 37 and the transform coefficients may both be coded in two portions, e.g., by combining features described with reference to FIGS. 5 and 6. This also applies to the encoder variations described further below with reference to FIGS. 7 and 8.

In FIG. 6, the context 55 is derived exemplarily a single transform coefficient 40c is used that immediately precedes the currently decoded transform coefficient 40d. However, any other amount of transform coefficients 40 in any combination and/or position (or rank) may be used instead.

The decoder 12 may be configured to in the sequentially, reverse relative to the scan order 39, decoding the transform coefficients 40 having a rank smaller than the predetermined rank 37, decode the currently decoded transform coefficient 40d of the respective coefficient-wise-entropy-coded temporal block with deriving the context 55 for decoding at least one bin of the first portion 53a by quantizing or thresholding a sum measure (e.g., a sum or a weighted sum) over absolute values of previously decode transform coefficients (e.g., all or a subset of previously decoded coefficients for the temporal block 140) within a template covering a predetermined number (e.g., two, three, four, five, six, or a power of two, or any other number, e.g., immediately preceding transform coefficients 40) of rank positions prior to the currently decoded transform coefficient 40d in scan order 39.

The decoder 12 may be configured to in the sequentially, reverse relative to the scan order 39, decoding the transform coefficients 40 having a rank smaller than the predetermined rank 39, decode the currently decoded transform coefficient 40d of the respective coefficient-wise-entropy-coded temporal block with derive a second context for decoding a sequence of greater-bins of the first portion, each of which being indicative of whether the residual sample value is greater than x+const with x being a rank of the respective greater-bin, depending on a quantized version of the rank of the currently decoded transform coefficient.

The decoder 12 (e.g., with reference to FIG. 5 or 6) may be configured to decode the transform coefficients 40 using a binarization comprising a significance bin (e.g., flag) and, in decoding the transform coefficient whose position in scan order 39 is equal to the predetermined rank 37, infer that this significance flag indicates non-zeroness. For example, inference of the significance for a first coefficient after (e.g., in reverse scan order 39) an endPos indicator (or flag or syntax element) may be performed. In case the predetermined rank 37 indicates a rank of transform coefficients, inference of this significance flag indicating non-zeroness may be performed for the transform coefficient whose position in scan order 39 is equal to or one rank less than the predetermined rank 37 (e.g., depending on whether the predetermined rank 37 indicates a last non-zero-coefficent or a first zero-coefficient). In case the predetermined rank 37 indicates a rank between transform coefficients 40, inference of this significance flag indicating non-zeroness may be performed for the transform coefficient whose position in scan order 39 is the largest rank that is less than the predetermined rank 37.

The decoder 12 (e.g., with reference to FIG. 5 or 6) may be configured to decode the transform coefficients 40 using a binarization comprising a significance bin and, in decoding the transform coefficient 40 whose position in scan order 39 is equal to the predetermined rank 37, decode the significance bin if the predetermined rank 37 falls onto a last rank in the scan order 39 (or reverse to the scan order 39), and infer that this significance flag indicates non-zeroness if the predetermined rank 37 does not fall onto the last rank in the scan order 39 (or reverse to the scan order 39). E.g., inference of a significance for the first coefficient after an endPos indicator may be performed, but not if endPos=0. E.g., if the predetermined rank 37 is the last rank in reverse scan order 39 (e.g., first rank in scan order 39), its value may be the only value that is not zero or may also be zero, which may require decoding a significance bin. However, if the predetermined rank 37 does not fall in the last rank in reverse scan order 39 (e.g., not fall in the first rank in scan order 39), there may be non-zero coefficients, indicating that no all transform coefficients are zero, which may make it inerrable that the transform coefficient 40 at the predetermined rank 37 is not zero without having to code a significance bin.

The decoder 12 (e.g., with reference to FIG. 5 or 6) may be configured to, in the sequentially, reverse relative to the scan order 39, decoding the transform coefficients 40 having a rank smaller than the predetermined rank 37, decode the currently decoded transform coefficient of the respective coefficient-wise-entropy-coded temporal block by deriving a context for decoding at least one bin of the first portion (e.g., first portion 53a as described with reference to FIG. 6, or applying a decoding of a first portion 53a as described in any form with reference to FIG. 6 to the decoding of FIG. 5) using one or more previously decoded transform coefficients of the respective coefficient-wise-entropy-coded temporal block using a context which depends on a rank of the currently decoded transform coefficient (e.g., and optionally also derived by quantizing or thresholding a sum measure over absolute values of previously encode transform coefficients within a template covering a predetermined number of rank positions prior to the currently encoded transform coefficient 40d in scan order 39, e.g., using templateClassIdx and/or NUM_TEMPLATE_SUM_CLASSES). For example, for at least one context model selection performed for decoding one specific bin (e.g., sign bin or any other bin) occurring at a fixed position in the used binarization for all transform coefficients of a block, this context selection is conducted depending on the position (or rank) of the respective residual transform coefficient that is currently decoded. For example, the context model selection selects a first context model for the respective bin if the position of the transform coefficient currently decoded belongs to a first set of positions and a second context model if the position of the transform coefficient currently decoded belongs to a second set of positions). However, more than two sets of positions (or ranks) may be used.

The context model selection may depend on the position in a frequency domain. For example, other context models may be used or selected for high frequencies than for low frequencies.

FIG. 7 shows a schematic view of a first variation of another example of an encoder 10 for encoding a digital time-varying signal 92 into a data stream 16. The data stream 16 encoded by the encoder 10 may be decodable by the decoder 12 shown in FIG. 5 (or any other decoder disclosed herein).

The encoder 10 is configured to encode the digital time-varying signal 92 into the data stream 16 in temporal blocks by encoding each of coefficient-wise-entropy-coded temporal blocks 140 of the temporal blocks 140 of the digital time-varying signal 92 by subjecting a time-domain residual signal 13 of the respective coefficient-wise-entropy-coded temporal block, ought (e.g., usable) to allow for reconstructing the respective coefficient-wise-entropy-coded temporal block by correcting a prediction signal 64 for the respective coefficient-wise-entropy-coded temporal block using the time-domain residual signal 13, to a transformation to obtain the transform coefficients 40, signaling in the data stream 16, a predetermined rank 37 indicating that, among the transform coefficients 40 of the coefficient-wise-entropy-coded temporal blocks, those transform coefficients having, along a scan order 39 defined among the transform coefficients, a rank greater than the predetermined rank are zero, sequentially, reverse relative to the scan order, encoding 57 the transform coefficients having a rank smaller than the predetermined rank 37 (e.g., smaller than or equal to the predetermined rank 37).

According to a first variation (e.g., usable in combination with decoder 12 shown in FIG. 5), the encoder 10 is configured to encode the predetermined rank 37 into the data stream 16 by encoding a coarse rank index 47a indexing one of several coarse rank positions along the scan order 39, and encoding a fine rank offset 47b pointing to the predetermined rank 37 relative to the one coarse rank position.

The encoder 10 may be configured to encode the predetermined rank 37 into the data stream by encoding the fine rank offset 47a using a fixed length code. For example, all bins may be bypass coded by the underlying CABAC engine (e.g., where the probability 0.5 is assumed for the value of all these bins). The encoder 10 may be configured to encode the fixed length code into the data stream at a code rate of 1.

The encoder 10 may be configured to encode the predetermined rank 37 into the data stream 16 by encoding the coarse rank index 47a using a truncated unary code if the one coarse rank position falls onto one of X leading coarse rank positions in scan order 39, and using the truncated unary code for X followed by a truncated binary code for indexing the one coarse rank position out of subsequent coarse rank positions following the X leading coarse rank positions in scan order 39, if the one coarse rank position does not fall onto the X leading coarse rank positions in scan order 39.

FIG. 8 shows a schematic view of a second variation of another example of an encoder 10 for encoding a digital time-varying signal 92 into a data stream 16. The data stream 16 encoded by the encoder 10 may be decodable by the decoder 12 shown in FIG. 6 (or any other decoder disclosed herein).

The encoder 10 is configured to encode the digital time-varying signal 92 into the data stream 16 in temporal blocks by encoding each of coefficient-wise-entropy-coded temporal blocks 140 of the temporal blocks 140 of the digital time-varying signal 92 by subjecting a time-domain residual signal 13 of the respective coefficient-wise-entropy-coded temporal block, ought (e.g., usable) to allow for reconstructing the respective coefficient-wise-entropy-coded temporal block by correcting a prediction signal 64 for the respective coefficient-wise-entropy-coded temporal block using the time-domain residual signal 13, to a transformation to obtain the transform coefficients 40, signaling in the data stream 16, a predetermined rank 37 indicating that, among the transform coefficients 40 of the coefficient-wise-entropy-coded temporal blocks, those transform coefficients having, along a scan order 39 defined among the transform coefficients 40, a rank greater than the predetermined rank 37 are zero, sequentially, reverse relative to the scan order 39, encoding 57 the transform coefficients having a rank smaller than the predetermined rank 37 (e.g., smaller than or equal to the predetermined rank 37).

According to the second variation (e.g., usable in combination with decoder 12 shown in FIG. 6), the encoder 10 is configured to, in the sequentially, reverse relative to the scan order 39, encoding the transform coefficients 40 having a rank smaller than the predetermined rank 37, encode 57 a currently encoded transform coefficient 40d of the respective coefficient-wise-entropy-coded temporal block by binary context-adaptively entropy encoding a first portion 53a of a binarization of the currently decoded transform coefficient 40d and encoding a remainder portion 53b of the binarization into the data stream 16, with deriving a context for encoding at least one bin of the first portion 53a using one or more previously encoded transform coefficients 40c (e.g., or any other one or more previously encoded transform coefficient in any other amount and/or combination) of the respective coefficient-wise-entropy-coded temporal block.

The encoder 10 may be configured to, in the sequentially, reverse relative to the scan order 39, encoding the transform coefficients 40 having a rank smaller than the predetermined rank 39, encode the currently encoded transform coefficient 40d of the respective coefficient-wise-entropy-coded temporal block with deriving the context for encoding at least one bin of the first portion 53a by quantizing or thresholding a sum measure over absolute values of previously encode transform coefficients within a template covering a predetermined number of rank positions prior to the currently encoded transform coefficient 40d in scan order 39.

The encoder 10 may be configured to, in the sequentially, reverse relative to the scan order 39, encoding the transform coefficients 40 having a rank smaller than the predetermined rank 39, encode the currently encoded transform coefficient 40d of the respective coefficient-wise-entropy-coded temporal block with derive a second context for encoding a sequence of greater-bins of the first portion, each of which being indicative of whether the residual sample value is greater than x+const with x being a rank of the respective greater-bin, depending on a quantized version of the rank of the currently encoded transform coefficient 40d.

The encoder 10 (e.g., with reference to FIG. 7 or 8) may be configured to encode the transform coefficients 40 using a binarization comprising a significance bin and, in encoding the transform coefficient whose position in scan order 39 is equal to the predetermined rank 37, infer that this significance flag indicates non-zeroness. For example, inference of a significance for a first coefficient after an endPos indicator may thusly be performed.

The encoder 10 (e.g., with reference to FIG. 7 or 8) may be configured to encode the transform coefficients 40 using a binarization comprising a significance bin and, in encoding the transform coefficient whose position in scan order 39 is equal to the predetermined rank 37, encode the significance bin if the predetermined rank 37 falls onto a last rank in the scan order 39 (or last rank in reverse to the scan order 39), and infer that this significance flag indicates non-zeroness if the predetermined rank does not fall onto the last rank in the scan order 39 (or reverse to the scan order 39). For example, inference of the significance may be performed for the first coefficient after an endPos indicator, but not if the endPos=0. E.g., if the predetermined rank 37 is the last rank in reverse scan order 39 (e.g., first rank in scan order 39), its value may be the only value that is not zero or may also be zero, which may require decoding a significance bin.

The encoder 10 (e.g., with reference to FIG. 7 or 8) may be configured to, in the sequentially, reverse relative to the scan order 39, encoding the transform coefficients 40 having a rank smaller than the predetermined rank 37, encode the currently encoded transform coefficient 40d of the respective coefficient-wise-entropy-coded temporal block by deriving a context for encoding at least one bin of the first portion 53a using one or more previously encoded transform coefficients of the respective coefficient-wise-entropy-coded temporal block using a context which depends on a rank of the currently encoded transform coefficient 40d. For example, for at least one context model selection performed for encoding one specific bin occurring at a fixed position in the used binarization for all transform coefficients of a block, this context selection may be conducted depending on the position of the respective residual transform coefficient that is currently encoded, e.g. the context model selection selects a first context model for the respective bin if the position of the transform coefficient currently encoded belongs to a first set of positions and a second context model if the position of the transform coefficient currently encoded belongs to a second set of positions. For example, context model selection may depend on the position in the frequency domain, e.g., other context models may be used for high frequencies than for low frequencies.

Further is provided a method for decoding a digital time-varying signal 92 from a data stream 16. The method may be a method performed by any decoder 12 disclosed herein.

Further provided is a method for encoding a digital time-varying signal 92 into a data stream 16. The method may be a method performed by any encoder 10 disclosed herein.

In the following, further examples are described for coding a digital time-varying signal. Features of embodiments described above may be combined with features of embodiments described in the following in any combination and vice versa.

### Coding of Digital Time-Varying Signal Using Entropy Coding

### 1. Entropy Coding of Residual Data for Waveform Signals

Digital data to be compressed with NPC (near perfect compression) may consist of one or more channels of one-dimensional sequences of (e.g., integer) samples. During coding, the data may be partitioned into blocks of samples that are, for example, either coded samplewise (e.g., sample-wise in temporal blocks) or blockwise (e.g., coded in transform coefficients of a transformation from a time-domain to a frequency-domain).

In case of samplewise coding the samples of a block (e.g., a temporal block 140) may be coded sequentially in a way, that each sample can be fully reconstructed by the decoder (e.g., any decoder described herein) before the next sample is processed. Thus, during the decoding of a given sample (e.g., currently decoded sample) all previously decoded samples of the block (or a subset thereof)- and therefore the information they hold-can be used (e.g. for prediction, context-modelling, etc.). For the samplewise coding, two different exemplary approaches (e.g., methods) are presented below (with reference to section 1.1 and 1.2).

With blockwise coding, not single samples but whole blocks of samples may be fed into coding stages like prediction, residual transformation and entropy coding of the transformation coefficients.

### 1.1 Samplewise Entropy Decoding (First Method)

### 1.1.1 Binarization and Coding Scheme

If a given block of samples is decoded samplewise, each reconstructed sample may comprise (or be composed of) a prediction (e.g., prediction sample value 64, e.g., prediction signal) and an binarized and entropy coded residual value res_val (residual sample value 80) which may be decoded as follows.

First, a (context-modeled, see 1.1.2) sig_flag (e.g., significance flag, a first predetermined bin 27a) may be received received. If the sig_flag is equal to zero (e.g., indicating that the residual sample value 80 is zero), the residual value res_val may be set to zero as well and decoding of res_val may be complete.

If sig_flag equals one (e.g., indicating that the residual sample value 80 is not zero), res_val may be set to one (e.g., in order to be potentially set to a different value, e.g., depending on subsequent bins or code). Now, a (context-modeled, see 1.1.2) sign_flag (e.g., indicating a mathematical sign of the residual sample value 80) may be received and, for example, stored for later use (but may be applied during any step). Next, a value numGreaterFlagsDecoded may be initialized with zero and a (context-modeled, see 1.1.2) greaterX_flag (e.g., greater-bin 27b, e.g., a first greater-bin 27b of a sequence of greater-bins27b-e) may be received (e.g., indicating that the residual sample value 80 is greater than X, e.g., greater than one) and numGreaterFlagsDecoded may then be set to one. Subsequently, it may be checked for further greaterX-flags, e.g., greaterX-flags having a value of one. As long as greaterX_flag equals 1 and numGreaterFlagsDecoded is smaller than bounding paramter maxNumGrXFlags (e.g., first maximum value), the following steps may be performed in a loop: increase res_val by one, receive and overwrite greaterX_flag, increase numGreaterFlagsDecoded by one. This loop resembles a variable length unary decode.

For example, maxNumGrXFlags may be four, wherein a greater2_flag, greater3_flag, and a greater4_flag may be received. If after a greater2_flag of one, a zero is received, the loop may end with the residual sample value 80 having a value of 3.

Now, if the last received greaterX_flag is equal to one (meaning the loop was ended due to numGreaterFlagsDecoded>=maxNumGrXFlags) res_val is increased by one once more and a remainder remAbsLevel (which may indicate a remainder value for the residual sample value 80 that possibly exceeds the last or greatest X) is decoded as follows:

To start, values remAbsLevel, log2NumElemNextGroup and ctxIdx are all intialized with zero. Now, a remAbs_flag is received using ctxIdx as a context model identifier. If remAbs_flag is equal to zero decoding of remAbsLevel (which equals 0 at this point) is complete (e.g., which may indicate that an absolute value for the residual sample value 80 has a value of X+1 of the last greaterX_flag). However, if remAbs_flag is not equal to zero remAbsLevel, log2NumElemNextGroup and ctxIdx may all be increased by one. Now, in a loop, remAbs_flag is received using ctxIdx as the context model identifier (e.g., received from the data stream 16 and decoded using a context model identified based on ctxIdx). The loop may break if a zero bin is received. Within the loop (e.g., as long as non-zero bin are received), for each remAbs_flag that is equal to one the following steps are performed in a loop: increase remAbsLevel by 1<<log2NumElemNextGroup (e.g., with a left shift operator “<<”, e.g., by increasing remAbsLevel by a value of two to the power of log2NumElemNextGroup), increase log2NumElemNextGroup by one, increase ctxIdx by one. Finally, after the loop has ended (e.g., a zero bin is received and/or a maximum loop count is reached), log2NumElemNextGroup bins are received using EP-coding (e.g., Exponential-Golomb coding), interpreted as an integer and added to remAbsLevel which concludes decoding of remAbsLevel.

Now, res_val from earlier is increased by remAbsLevel. As a last step, if the sign_flag received earlier is 1, the res_val may be given a negative sign.

At this point the residual value res_val is fully decoded and may be added to the prediction value (e.g., prediction signal 64) to form the reconstructed sample.

### 1.1.2 Context Model Derivation

One approach to derive a context model may be to have a value templateSum as a context classifier which is computed right before the decoding of the next sample as follows: templateSum may be set to the sum (e.g., a sum measure, e.g., a normal sum or a weighted sum) of the absolute values of the last N_TEMPLATE_SUM (e.g. 3 or any other number such as 2, 4, 5, 6, or higher) residual values of a block. However, other sum measures may be used, e.g., using non-absolute numbers and/or squared numbers. If there are less than N_TEMPLATE_SUM residual values available (e.g. at the beginning of a block) they may be assumed zero for the computation of templateSum. For example, if the previously coded sample values are 5, 8, and −13, 3_TEMPLATE_SUM may be determined as 5+8+13=26. In a different example, if a third sample of a temporal block 140 is currently decoded and only two previously coded samples with values 5 and 8 are available, 3_template_SUM may be determined as 5+8=13.

1.1.2.1 sig_flag Context Model Derivation

A context model index used for the sig_flag may depend on the last received residual value ras_val_last (i.e. res_val at the position of the last decoded sample, e.g., previously decoded residual sample value 80) and may be set to one of three possible values corresponding the the following cases: ras_val_last<0, ras_val_last=0, ras_val_last>0.

1.1.2.2 sign_flag Context Model Derivation

A context model index used for the sign_flag may depend on the last received residual value ras_val_last (i.e. res_val at the position of the last decoded sample, e.g., previously decoded residual sample value 80) and may be set to one of three possible values corresponding the the following cases: ras_val_last<0, ras_val_last=0, ras_val_last>0.

1.1.2.3 greaterX_flag Context Model Derivation

The derivation of ctxIdx_greaterX, which may be the context model index used for the greaterX_flag, may depend on the two values numGreaterFlagsDecoded (e.g., indicating an amount of greaterX_flags decoded for the current sample) and templateSum (e.g., a sum measure determined based on previously coded sample values, e.g., as described above) and may follow the derivation rule

ctxId x_{greaterX}=bₘₐₓ·a+b

while a is a non-negative integer set to numGtxFlagsCoded (which is non-negative, e.g., based on or equal to numGreaterFlagsDecoded) clipped by upper bound GTX_MAX_NUM_CTX_MODELS −1 (e.g. 1), bₘₐₓ is set to TEMPLATE_SUM_CLASSES_GRX (e.g. 2) and b is set to templateSum>>TEMPLATE_SUM_BITSHIFT_GRX (which is non-negative) clipped by upper bound TEMPLATE_SUM_CLASSES_GRX−1.

### 1.2 Samplewise Entropy Coding, Second Method

The second method (or approach) is used in the case that no inverse quantization is invoked at the decoder but might also be used in other scenarios.

First, a value borderCtxtSwitch may be set to either zero or to a number of transformation weights (e.g., a number of transform coefficients). Additionally, a value absSumCoeffs may be initialized with zero.

Now, the coefficients (e.g., transform coefficients 40) of the block (e.g., temporal block 40) may be decoded sequentially (in a loop) in time order starting with the position following the last position within the temporally preceding block. After the decoding of each coefficient, the value absSumCoeffs is updated by increasing it with a value updateVal if updateVal is non-negative. The value updateVal may be first set to the absolute value of the just decoded coefficient (e.g., previously decoded coefficient) and then decreased by CUTOFF_FOR_RICE+1, with CUTOFF_FOR_RICE being a predefined value (e.g. 4 or any other positive integer). The value absSumCoeffs may be used for context model derivation while decoding a coefficient.

Now, within the loop, each coefficient may be decoded as follows:

The value res_val may be initialized with zero and may represent the current coefficient to be decoded. Now, a sig_flag is received, which may be context modelled (e.g. using a single context model, e.g., as described above) indicating if the current coefficient is not zero (i.e. sig_flag==1). If the sig_flag equals 0, the current res_val may be set to zero and decoding of the current coefficient is complete. However, if the sig_flag is equal to one (e.g., indicating that res_val is not zero), res_val may be increased by one and a sign_flag may be received (context-modeled, e.g. with a single context model, e.g., as described above) and stored for later use.

Now, a value numGreaterFlagsDecoded may be initialized with zero and a (e.g., context-modeled, see 1.2.2.1 below) greaterX_flag may be received and numGreaterFlagsDecoded may be then set to one. As long as greaterX_flag equals 1 and numGreaterFlagsDecoded is smaller than predefined bounding paramter CUTOFF_FOR_RICE (e.g. 4 or any other integer value) the following steps may be performed in a loop: increase res_val by one, receive and overwrite greaterX_flag, increase numGreaterFlagsDecoded by one. This loop resembles a variable length unary decode.

Now, if the last received greaterX_flag is equal to one (e.g., meaning the loop was ended due to numGreaterFlagsDecoded>=CUTOFF_FOR_RICE) res_val may be increased by one once more and a remainder remAbsLevel may be decoded as follows:

First, a value riceParam that may depend on the current position (e.g., rank) within the block and the current value of absSumCoeffs may be computed (e.g., as described in 1.2.2.2). Now, remAbsLevel may be coded in two parts, namely a variable length unary code part (e.g., first portion 53a) resulting in the value q and a fixed length EP-coded part (e.g., remainder portion 53b) using riceParam bins, resulting the value r that is interpreted as an (non-negative integer). The bins that signal the unary code may be context modeled in a way, that a context model index is initialized with zero and then incremented by one after each received bin, e.g., up to a predefined threshold value (e.g. MAX_NUM_CTXT_RICE−1, MAX_NUM_CTXT_RICE=8, or any other integer value). Finally, remAbsLevel may be set to the sum of q·2^{riceParam} and r.

Now, res_val from earlier may be increased by remAbsLevel. As a last step, if the sig_flag received earlier is 1, the res_val may be given a negative sign.

At this point the coefficient value res_val is fully decoded (additionally absSumCoeffs may be updated as described earlier) and the next coefficient in order will be decoded.

1.2.1.1 greaterX_flag Context Model Derivation

The context model used to code a greatX_flag may be identified by a value greaterXCtxId.

Before the first greaterX_flag is received, the value greaterXCtxId may be set to zero if the position of the current coefficient within the block is smaller than borderCtxtSwitch and else, greaterXCtxId may be set to one. For example, a second context for decoding a sequence of greater-bins of the first portion depending on whether the current sample position 17a is, reverse to the sample order (e.g., in FIG. 2 in a distance measured from the sample position 17a towards the left), distanced by less than K sample positions from a previously decoded temporal block.

Now, after each received greaterX_flag, the value greaterXCtxId may be increased by 2 as long as numGreaterFlagsDecoded<=MAX_RANGE_GTX_SEP_CTXT (e.g. 6 or any other integer value).

### 1.2.1.2 Derivation of Value Riceparam

The signal-adaptive value riceParam may depend on the value absSumCoeffs from earlier (e.g., a value updated by incrasing it with an absolute value of a just decoded coefficient, e.g., an absolute sum measure over the predetermined sample value of all preceding sample positions) and a number of already decoded coefficients (denoted numCoeffsForSum, e.g., of the same block pertaining to a temporal block 140) like follows: The value riceParam may be initialized with one. Now, absSumCoeffs may be iteratively compared to an ascending sequence of threshold values and each time a threshold is surpassed, riceParam may be incremented by one. The threshold values may be proportional to numCoeffsForSum (e.g. numCoeffsForSum*a, e.g., with a in [2,5,15]). In other words, riceParam may indicate a classification index of the ratio of absSumCoeffs and numCoeffsForSum.

### 1.3 Blockwise Entropy Decoding

In Contrast to samplewise coding described earlier, blockwise coding may include a transformation stage (e.g., from a time domain to a frequency domain for encoding and vice versa for decoding) applied to the full residual block of samples (i.e. the difference of the original block and the predicted block) and a binarization involving multiple samples or even all the (e.g., quantized) residual samples of the block. Different coding schemes (e.g. quantization, binarization, entropy coding, etc.) may be applied in different scenarios.

Specifically, while decoding a block of samples, a flag may be received indicating whether to use a block-based transform like the Discrete Cosine transform or not to use it. Depending on this scenario, different methods of entropy coding are proposed.

### 1.3.1 Binarization and Coding Scheme of Blocks Including a Block-Based Transform

As described earlier, with blockwise coding, there may be no intermediate reconstruction of the samples during decoding thus (e.g., reconstruction of a sample of a temporal block 140 may not be completed before decoding another sample of the same temporal block 140 begins), all residual samples (or transform coefficients) of the block may be decoded before a reconstruction stage.

To start with, a value endPos is received (e.g., see description in 1.3.1.1) indicating a first sample position (e.g., the predetermined rank 37) within the block (e.g., of transform coefficients) a zero coefficient (e.g., a transform coefficient having a value of zero) occurs which is only followed (e.g., in scan order 39) by more zero coefficients for the rest of the block. This may be beneficial if, for example, an energy compacting transform (e.g. DCT) was applied to the residual before quantization and encoding. In other words, coefficients at positions (or ranks) ranging from endPos until the (rightmost, e.g., in scan order 39) end of the block do not need any further coding and can be set to zero at the decoder.

Now, the remaining coefficients of the block may be decoded sequentially in reversed order (e.g., reverse to scan order 39) starting with position endPos-1 and finishing with position zero (e.g., a first coefficient in scan order 39) like follows:

Before the decoding of each coefficient a value templateClassIdx may be derived (see desciption 1.3.1.3). A value res_val is initialized with zero and may represent the current coefficient to be decoded. Now, a sig_flag may be received which may be context modelled (see 1.3.1.4) indicating if the current coefficient is not zero (i.e. sig_flag==1). If the sig_flag equals 0 the current res_val may be set to zero and decoding of the current coefficient may be complete. However, the sig_flag may be inferred (and not explicitly transmitted) if the current sample position is equal to endPos −1 and greater zero (e.g., at a rank or position in a range of 1 to endPos−1), because the encoder ensures, that-if endPos is greater zero the coefficient at position endPos −1 is not zero, thus sending a sig_flag in this case would be redundant.

Next, if the sig_flag is equal to one, res_val may be increased by one and a sign_flag may be received (e.g., context-modeled, e.g. with a single context model) and stored for later use.

Now, a value numGreaterFlagsDecoded may be initialized with zero and a (e.g., context-modeled see 1.3.1.5) greaterX_flag may be received and numGreaterFlagsDecoded (e.g., indicating an amount of greaterX_flags decoded so far fur the currently decoded coefficient parameter) may be then set to one. As long as (e.g., subsequently received) greaterX_flag equals 1 and numGreaterFlagsDecoded is smaller than bounding parameter maxNumGrXFlags, the following steps may be performed in a loop: increase res_val by one, receive and overwrite greaterX_flag, increase numGreaterFlagsDecoded by one. This loop resembles a variable length unary decode.

If a greaterX-flag equals 0, res_val may be set to X.

Now, if the last received greaterX_flag is equal to one (e.g., meaning the loop was ended due to numGreaterFlagsDecoded>=maxNumGrXFlags) res_val may be increased by one once more and a remainder remAbsLevel may be decoded as follows:

To start, values remAbsLevel, log2NumElemNextGroup, and ctxIdx may be all intialized with zero. Now, a remAbs_flag is received using ctxIdx as a context model identifier. If remAbs_flag is equal to zero, decoding of remAbsLevel (which equals 0 at this point) may be complete. However, if remAbs_flag is not equal to zero, remAbsLevel, log2NumElemNextGroup, and ctxIdx may be all increased by one. Now, in a loop, remAbs_flag may be received using ctxIdx as the context model identifier. The loop may break if a zero bin is received. within the loop, for each remAbs_flag that is equal to one, the following steps may be performed in a loop: increase remAbsLevel by 1<<log2NumElemNextGroup, increase log2NumElemNextGroup by one, and increase ctxIdx by one. Finally, after the loop has ended, log2NumElemNextGroup bins may be received using EP-coding (e.g., exponential Golomb coding), interpreted as an integer and added to remAbsLevel which concludes decoding of remAbsLevel.

Now, res_val from earlier may be increased by remAbsLevel. As a last step, if the sig_flag received earlier is 1, the res_val is given a negative sign.

At this point the coefficient value res_val is fully decoded and the next coefficient in order will be decoded.

1.3.1.1 Decoding of endPos

The positional value endPos may be signaled in two stages. First, a value idxLastSubblock may be received (further described in 1.3.1.2) indicating an index (e.g., coarse rank index) of the (virtual) subblock endPos is located in (wherein a block of transformation coefficients may be subdivided into subblocks that can be indexed by the coarse rank index). Second, the value offset (e.g., fine rank offset) is received indicating a position within the previously signaled subblock (e.g., pointing to the predetermined rank relative to the one coarse rank position).

The (virtual) subblocks may be fixed in size. With the coding parameter LOG2_SUBBLOCK_SIZE_LAST (e.g. 2) that size may be defined as SUBBLOCK_SIZE_LAST=1<<LOG2_SUBBLOCK_SIZE_LAST.

The value offset may be EP-coded using LOG2_SUBBLOCK_SIZE_LAST bins (e.g., two bins for a subblock having a size of four) that cover the full range of SUBBLOCK_SIZE_LAST possible values.

Specifically, endPos may be initially set to (idxLastSubblock+1)*SUBBLOCK_SIZE_LAST (e.g. SUBBLOCK_SIZE_LAST=4) and then decreased by the value offset. The value offset (e.g., fine rank offset) may define an offset reverse or along the scan order 39.

1.3.1.2 Decoding of idxLastSubblock

The value idxLastSubblock (e.g., coarse rank index) may be decoded using a unary code. A value maxNumBins may be set beforehand and may resemble a maximum number of unary bins to receive. This can be done because idxLastSubblock is bound by the block size (the maximum number of subblocks may depend only on the block size which is known at the decoder at this point). It is noted that maxNumBins may be set to the maximum number of unary coded candidate indexes minus one because an explicit signalling of the final candidate would be redundant (e.g., if there are four candidates in total and three zero bins were already decoded meaning none of first three candidates were chosen by the encoder, there is no need to transmit an additional one bin because there is just one candidate left).

First, the value idxLastSubblock may be initialized with zero and then, in a loop, context-modeled bins (e.g., using idxLastSubblock as context index) may be received up to a maximum number of maxNumBins bins (e.g., maximum number of unary coded candidate indexes minus one). For each received bin, idxLastSubblock may be either increased by one (and therefore changing the context model that may be used to decode the next bin) if the last bin received equals 0 or the loop ends if a one bin was received (not increasing idxLastSubblock). For example, if three bins are received with values 001, idxLastSubblock may be increased twice (wherein the context model may change a total of two times due to receiving two zero bins) and the loop ends after receiving the bin with a value of one.

However, if the size of the block exceeds a certain threshold (i.e. the number of candidates for idxLastSubblock and therefore the number of unary bins exceeds a certain threshold) the procedure from above may be altered: Instead of breaking after maxNumBins bins the loop may end earlier, namely by the time the current value of idxLastSubblock exceeds a predefined value MAX_VAL_UNARY (e.g. 32, or any other number, e. g,. a different power of two) and a remainder value offsetVal in form of a truncated binary code is received to signal which one of n=maxNumBins+1−MAX_VAL_UNARY remaining candidates was chosen by the encoder. Finally, idxLastSubblock may be increased by offsetVal and decoding of idxLastSubblock is completed.

1.3.1.3 Derivation of templateClassIdx

First, a value templateSum may be computed as the sum of the absolute values of a predefined number (TEMPLATE_SIZE, e.g. 3) of last decoded coefficients (e.g., a sum measure over absolute values of previously decode transform coefficients within a template, e.g., covering a predetermined number of rank positions prior to the currently decoded transform coefficient in scan order). If there are less previously coded coefficients available (e.g. near a block border) the sum may be computed with only the values available. The value templateSum may be non-negative being a sum of absolute values.

Now, templateClassIdx may be set to a smallest possible value so that templateSum<=templateClassIdx*TEMPLATE_CLASS_THR is true with TEMPLATE_CLASS_THR being a predefined value (e.g. 1) (e.g., thresholding an absolute sum measure). However, templateClassIdx may be smaller than a predefined value NUM_TEMPLATE_SUM_CLASSES (e.g. 3 or any other integer).

1.3.1.4 sig_flag Context Model Derivation

A context model index sigCtxId used to signal the sig_flag may depend on a position pos of the current coefficient (e.g., rank of current transform coefficient 40d) within the block and the value templateClassIdx described earlier. First, sigCtxId may be initialized with zero and, if applicable, set to the smallest possible value so that pos>bordersSig[sigCtxId] while bordersSig may be a predefined array with entries resembling classification interval borders (e.g. {0, 1, 2, 3, 7, 11, 15, 23, 31, 38, 46, 54, 62, 78, 94}).

Now, with templateClassIdx being one value out of NUM_TEMPLATE_SUM_CLASSES candidates (i.e. templateClassIdx lies within interval [0, NUM_TEMPLATE_SUM_CLASSES−1]), sigCtxId may be first multiplied with NUM_TEMPLATE_SUM_CLASSES and then increased by templateClassIdx.

1.3.1.5 greaterX_flag Context Model Derivation

A context model index greaterXCtxIdx used to signal the greaterX_flag may depend on the positon pos of the current coefficient.

First, greaterXCtxIdx may be initialized with zero and, if applicable, set to the smallest possible value so that pos>bordersGreaterX[greaterXCtxIdx] while bordersGreaterX may be a predefined array with entries resembling classification interval borders (e.g. {0, 1, 2, 3, 7, 11, 15, 23}).

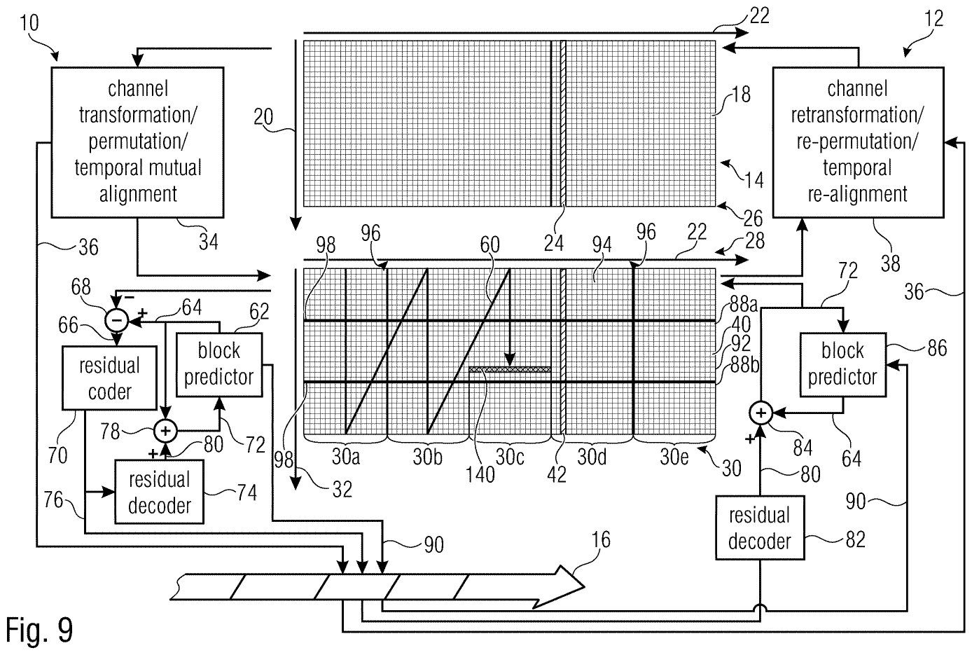

The above description is now extended in the following by the presentation of further embodiments in form of claims. Before this, however, the description proceeds with a presentation of a possible framework or codec into which the embodiments described above as well as the embodiments described further below may be built into. Many details described in this framework are, however, optional when being combined with any of the above or subsequently described embodiments. To be more precise, the framework is described with respect to FIG. 9 which shows an encoder for encoding a multi-channel digital signal 14 into a datastream 16 as well as decoder 12 for decoding the multi-channel digital signal 14 from datastream 16. This description of FIG. 9 shall be seen as a presentation of new embodiments of the present application which result when combining any of the embodiments described above or any of the embodiments described subsequently is combined with the decoder 12 or encoder 10 of FIG. 9 either by adopting all details/functionalities described with respect to FIG. 9 or with leaving-out some of the details/functionalities described with respect to FIG. 9. Sometimes such “optional” features of FIG. 9 are explicitly identified as being optional with respect to the combination of the previously and subsequently described embodiments, but the just-mentioned possible combinations of the previously/subsequently explained embodiments with the description of FIG. 9 shall not be restricted to the these explicitly identified variations of FIG. 9 in terms of leaving-out certain features.

In FIG. 9, the multi-channel digital signal 14 is illustrated by way of an array of samples with the samples being illustrated as small squares 18. Each line/row corresponds to a certain channel of the multi-channel digital signal 14. Each channel of signal 14 may have associated therewith a respective channel ID and FIG. 9 shows these channels as being ordered according to their channel ID along vertical axis 20 which, thus, corresponds to a “source” channel axis 20. The horizontal axis 22 corresponds to time so that samples 18 forming one column, or being horizontally aligned, are samples belonging to one common time instant. Such set/column of temporally co-located samples 18 is illustrated in FIG. 9 at 24.

Each channel, thus, forms a digital time-varying signal or time/amplitude or time-to-amplitude signal. The multi-channel digital signal m might have been obtained by at least one of Electrocardiography, Electroencephalography, Electromyography or seismic measurement. Differently speaking, the multi-channel digital signal might be a bio-physiological waveform data such as an electroencephalography (EEG) signal, an electrocardiogram (ECG), or an electromyography (EMG) signal, or seismic waveform data. However, each channel/signal might alternatively be another sort of waveform signal data such as scalar media data such as an audio signal and the signal 14 might be a multi-channel audio signal.

FIG. 9 illustrates the option according to which signal 14 is not coded directly, i.e., in the original domain 26, but in a so-called “coded domain” 28 which might differ from the original domain 26 by one or more of 1) channel transformation, 2) channel permutation and 3) temporal mutual channel alignment. The channel transformation, if applied, transforms, per sample time instant, a set or column 24 of samples from domain 26 to domain 28. Thus, in domain 28, the sample pitch and the time axis is the same as in domain 26, but the meaning of the channels is different, i.e., the “source” channels of domain 26 become transformed channels in domain 28. Accordingly, the vertical axis in FIG. 9 for domain 28 is denoted as 32. Note that the channel transformation might leave the number of channels unchanged so that there is the same number of channels in domain 26 as well as domain 28, but different approaches are also possible. Generally, the channel transformation would aim at reducing redundancy and trying to condense the channels'energy onto a fewer number of channels in domain 28. As said, the channel transformation is optional. Accordingly, in general terms, the channels in domain 28 are called “coded channels” in order to distinguish them from the “original” or “source” channels of digital signal 14 in domain 26. The permutation is also optional and may be used in combination with, or without, the channel transformation. If used in combination with the channel transformation, the permutation may be performed prior to and/or or subsequent to the channel transformation in order to permute/sort the source channels prior to transformation and the coded channels subsequent to the channel transformation. The channel transformation might be a DCT, DST, FFT or any other transformation. The temporal mutual alignment is also optional and might be seen as a constant temporal alignment between the source channels or the coded channels.

The module in encoder 10 performing the one or more of channel transformation, channel permutation and temporal mutual alignment is indicated in FIG. 9 as block 34. Side information 36 might be used in order to signal information on one or more of the following: 1) The channel transformation used, 2) information on the permutation(s) among the source channels and/or coded channels and 3) information on the mutual temporal alignment/delays between the source channels or coded channels wherein the temporal mutual alignment might be restricted to full sample precision. A corresponding block 38 in decoder 12 performs the reverse step, i.e., performs one or more of: 1) a channel retransformation, 2) a re-permutation of the source channels and/or coded channels and 3) a temporal re-alignment of the source channels or coded channels. Note, that if no channel transformation takes place, the coded channels are, in fact, equal to the source channels except for being temporally mutually aligned or being differently sorted due to permutation. Block 38 might be controlled by the before-mentioned side information 36.

Thus, the “actual coding” relates to the coded channels in domain 28. In the coded domain 28, the coded channels are depicted in FIG. 9 as lines or rows of samples 40, each extending along time axis 22, the coded channels being depicted one on top of the other along coded channel axis 32-potentially ordered according to a coded channel ID the have associated therewith-so as to result into an array of samples 40. Again, although FIG. 9 depicts the case that the number of source channels equals the number of coded channels, the number might be different. Further, if channel transformation is used, while there is no longer a clear association between source channels on the one hand and coded channels on the other hand, the temporal association remains: For each temporally co-located samples 24, there is a corresponding temporally co-located set 42 of samples 40 of the coded channels, wherein the set 42 in domain 28 is a column and might be a set of horizontally mutually offset samples in case of, and according to, the mutual temporal alignment, if applied. In case of FIG. 9, it has been assumed that no such temporal alignment took place so that both sets 42 and 24 are pure columns in the time/channel representation.

The actual coding is done in units of so-called temporal blocks 30. The term “temporal block” 30 is used so as to denote both a temporal portion of the multi-channel signal in domain 28, i.e., the set of coded channels, as well as a temporal portion of a certain coded channel. That is, for each temporal block 30, each coded channel has a temporal block such as block 140 depicted for some temporal block 30c and same are mutually co-located. The coding is done sequentially along these blocks 140, by following a coding/decoding order, which traverses the blocks 140 temporal block 30 by temporal block 30 with traversing temporally co-located blocks of the coded channels along a channel order corresponding to the order of the coded channels along axis 32. This coding/decoding order is illustrated in FIG. 9 at 60. That is, in case of temporal block 140 being the block currently to be coded/decoded, the previously decoded/encoded temporal blocks include all preceding temporal blocks of all coded channels as well as the temporally co-located temporal blocks of coded channels preceding the coded channel 92 of temporal block 140 in channel order. These previously coded/decoded temporal blocks and their samples are illustrated in FIG. 9 by way of shading. In this regard, note that in FIG. 9, merely one temporal block 140 has been illustrated explicitly in order to reduce the complexity of FIG. 9. Thus, in the specification herein, reference sign 140 is sometimes used to indicate the currently encoded/decoded temporal block or to stand representatively for all temporal blocks. Further, as depicted in FIG. 9, the partitioning of signal 14 into temporal blocks 30 and 140, respectively, might be done in a manner so that these blocks 30 and 140, respectively, are non-overlapping.

The actual coding in units of the temporal blocks 140 is performed predictively. That is, the encoder 10 comprises a block predictor 62 which predicts the samples of the currently coded temporal block 140, thereby yielding a prediction signal 64, and the prediction residual 66 formed by a subtraction between the actual sample values of temporal block 140 and the predicted samples of prediction signal 64 formed at a subtractor 68 is coded into the datastream 16 by residual coder 70. The residual coding in residual coder 70 may, or may not, involve a coding error by means of quantization. In any case, block predictor 62 uses the reconstructable version as being available by previously coded temporal blocks in order to obtain the prediction signal 64. This reconstructable version 72 might be derived at encoder 10 by means of a residual decoder 74 which reverses potential coding loss, such as quantization by means of dequantization, manifesting itself in the residual signal 76 coded into datastream 16, and an adder 78 which sums-up prediction signal 64 and the reconstructable residual signal 80 as obtained by residual decoder 74.

The decoder 12 decodes the coded channels from data stream 16 in a corresponding manner, i.e., in units of the temporal blocks 30 or in temporal blocks 140, respectively, and using predictive decoding. To this end, the decoder 12 comprises a residual decoder 82, an adder 84 and a block predictor 86 which correspond to, and are mutually connected in the same manner as, elements 74, 78 and 62 of encoder 10. That is, the residual decoder 82 derives from the residual signal 76 in data stream 16 the reconstructable residual signal 80 for a currently decoded temporal block 140 which is then subject to addition with prediction signal 64 derived by block predictor 86 for temporal block 140 on the basis of the reconstructed version 72 of previously decoded temporal blocks at adder 84. The output of adder 84, thus, yields the reconstructed version 72 of the currently decoded temporal block 140 and becomes part of the pool of already decoded samples of previously decoded temporal blocks when the temporal blocks of the coded channels are, in this manner, traversed along coding/decoding order 60 so as to reconstruct the coded channels in the coded domain 28.

In order to enable a high degree of random access capability, some of the temporal blocks 30 may be coded in a random access manner meaning that the coded channels therein are coded independent from previous temporal blocks 30. Imagine, for instance, that temporal blocks 30b and 30e are random access temporal blocks. Then, none of the temporal channel blocks 140 in temporal block 30b as well as 30e would depend on any preceding temporal block 140 such as none temporal block within temporal block 30a forming a coding dependency basis for any temporal channel block 140 in temporal block 30b and none of the temporal channel blocks 140 within temporal blocks 30a to 30d forming a coding dependency basis for any of the temporal channel blocks 140 within temporal block 30e. Thus, in other words, coding dependencies are restricted so as to not reach-out beyond the border of a random access temporal block 30b and 30e towards any preceding temporal block 30. Such restriction might also hold for intermediate temporal blocks 30c to 30d between random access temporal blocks 30b and 30e in that same may not depend on any temporal block preceding the leading one among the random access temporal blocks 30b and 30e, here block 30b. Accordingly, leading temporal borders of the random access temporal blocks 30b and 30e are indicated by bold lines in FIG. 9.

Further, it might be that the coding of the coded channels also interrupts or restricts inter-channel dependencies by coding one or more of the coded channels as random access coded channels so that coding dependencies of these random access coded channels, or even these random access coded channels and the intermediate coded channels therebetween, are restricted so as to not reach-out beyond such a random access coded channel toward any coded channel preceding that random access coded channel in channel order along axis 32. Two such random access coded channels 88a and 88b and their associated inter-channel dependency borders are illustrated in FIG. 9.

The block predictor 62 and 86 of encoder 10 and decoder 12, respectively, operate synchronously, i.e., they generate the same prediction signal 64 based on the previously encoded/decoded samples of previously encoded/decoded temporal blocks 140. On encoder side 10, the prediction for a certain temporal block 140 may be accompanied or determined by one or more prediction parameters. Same might be determined on encoder side based on a rate/distortion optimization. These prediction parameters 90 are coded into data stream 16 and they are decoded from data stream 16 and used by block predictor 86 so as to perform the same prediction.

It might be that encoder 10 and decoder 12 support more than one prediction mode. For instance, encoder 10 and decoder 12 may support an intra prediction mode (which mode may also be called block-copy mode) according to which the currently encoded/decoded temporal block 140 is predicted based on the reconstructable sample values of previously encoded/decoded temporal blocks of the same coded channel to which the currently encoded/decoded temporal block 140 belongs, which is coded channel 92 in the example of FIG. 9. Additionally or alternatively, encoder 10 and decoder 12 may support an inter-prediction mode (which mode may also be called cross-channel prediction mode) according to which the currently encoded/decoded temporal block 140 is predicted based on the reconstructable sample values of previously encoded/decoded temporal blocks of coded channels preceding-in coding order 32-the coded channel 92 to which the currently encoded/decoded temporal block 140 belongs. Additionally or alternatively, there may be a mixed prediction mode according to which the prediction signal 64 is obtained by both, reconstructed/reconstructable sample values of previously encoded/decoded temporal blocks of coded channel 92 itself as well as reconstructed/reconstructable sample values of coded channels preceding coded channel 92 in channel order along axis 32. Beyond this, there may be temporal blocks 140 which are coded without any prediction at encoder 10 and decoded without any prediction at decoder 12 such as the first temporal blocks in the tiles 94 resulting from mutually separating the temporal blocks by means of the random access borders 96 on the one hand and the random access channel borders 98 on the other hand. This corresponds to the prediction signal 64 being set to zero and this may form an additional mode which could be called bypass mode. Additionally, or alternatively, there may be other modes such as ones deriving a DC predictor or linear function predictor for block 64 based on immediately preceding samples of block 140. The prediction parameters 90 may, thus, contain for a currently encoded/decoded temporal block 140 a prediction mode flag or prediction mode indicator indicating the prediction mode to be used for this currently encoded/decoded temporal block 140 and, optionally, one or more parameters parameterizing the prediction mode to be used for this currently encoded/decoded temporal block 140.

The aforementioned coding dependencies ought not to cross any of the borders 96 and 98 not only result from the just-described sample prediction capabilities of block predictor 62 and 86, respectively, but may optionally also result from other mechanisms such as parameter prediction according to which parameters such as the aforementioned prediction parameters 90 for a certain temporal block 140 are predicted based on coding parameters conveyed in the data stream 16 for any previous temporal block, or context derivation for context-adaptive entropy coding/decoding any coding parameter such as the prediction parameters 90 or any other side information such as side information 76 and 36 for temporal block 140 based on any coding parameter conveyed in the data stream 16 for any preceding temporal block.

That is, summarizing, the encoder 10 encodes the multi-channel signal 14 by transferring it into the coded domain 28 and then coding the coded channels into data stream 16 in the just-described block-wise and predictive manner, wherein decoder 12 decodes the coded channels of coded domain 28 from data stream 16 and the corresponding block-wise and predictive manner with then gaining the multi-channel signal 14 in its original form 26 based on the coded channels in coded domain 28 by means of segment 38. As said, the channel transformation is optional and if not used, each sample 40 in the coded domain 28 really corresponds to one sample 18 in the original domain 26. If, further, the temporal mutual alignment is not used, each sample 40 exactly corresponds to a sample 18 in the original domain 26 at exactly the same time instant or, differently speaking, all temporally co-located samples 40 in coded domain 28 remain mutually temporally co-located in the original domain 26.

As mentioned before, FIG. 9 only represents a possible “framework” into which the previously described embodiments and the embodiments described subsequently may be built into. Many modifications may be performed with respect to FIG. 9, and some of these modifications might be mentioned in the subsequent description with respect to certain ones of the subsequently described embodiments, but these modifications shall then be treated as being also applicable with respect to other ones of the subsequently described embodiments. Further, as a final note, and without being treated as forming an exclusive list of further possible amendments of the description of FIG. 9, it shall be noted that the temporal blocks 30 might, other than illustrated in FIG. 9, vary in block length rather than being of a constant length as depicted in FIG. 9. For instance, encoder 10 may decide on the length of blocks 30 and signal the block length of blocks 30 (and the corresponding temporal blocks 140 of the coded channels) within data stream 16. Further, although not described before, it might be that residual coder and residual decoder 70 and 82 may use transform coding/decoding in order to convey the residual signal 76 in data stream 16. That is, the residual signal 80 may be conveyed in data stream 16 in transform domain by way of transform coefficients in residual signal 76. The transform domain might be a DCT, DST or an FFT. The transform may be non-overlapping, i.e. it may only transform residual signal 80 and its re-transform may only cover residual signal 76 within block 140, and/or may be non-windowed, i.e. the residual signal might be transformed without any transform window used to temporally shape the residual signal 80 before the transform. The transform domain, i.e. the transformation leading from time domain to transform domain which is used by the encoder to transform the prediction residual signal 80 to be coded und the corresponding re-transformation leading from transform domain to time domain which is used by the decoder to derive the prediction residual signal 80, or the transformation, might be selected from a set of available transforms including, for instance, one or more of 1) one or more DCTs, 2) one or more DSTs and 3) an identity transform according to which the prediction residual signal 80 is coded into the data stream 14 in time domain directly. Some deblocking processing might be used to avoid blocking artifacts. If, alternatively, an overlapped transform is used, an overlap-add processing with re-transforms of immediately preceding/succeeding temporal blocks of the same coded channel might be used in order to completely reconstruct the current temporal block's 140 residual signal 76. Besides such transform-(residual)-coded blocks there might be temporal blocks 140 which, additionally or alternatively, are coded using, besides the block prediction by block predictor 62/86—which could be called a primary prediction—a secondary sample-wise prediction of the residual samples in residual block 66 such as by predicting a current sample's residual sample by means of already decoded values of preceding—in sample coding order—residual samples in block 66 or 80, with then correcting same by means of a secondary-prediction-residual sample decoded from the data stream 16. The secondary-prediction-residual samples for such a block may coded into the data stream en block in a transform domain or sample-wise in time domain.

Although some aspects have been described in the context of an apparatus, it is clear that these aspects also represent a description of the corresponding method, where a block or device corresponds to a method step or a feature of a method step. Analogously, aspects described in the context of a method step also represent a description of a corresponding block or item or feature of a corresponding apparatus. Some or all of the method steps may be executed by (or using) a hardware apparatus, like for example, a microprocessor, a programmable computer or an electronic circuit. In some embodiments, one or more of the most important method steps may be executed by such an apparatus.

### Further Remarks:

Also, it should be noted that individual aspects described herein can be used individually or in combination. Thus, details can be added to each of said individual aspects without adding details to another one of said aspects.

Moreover, features and functionalities disclosed herein relating to a method can also be used in an apparatus (configured to perform such functionality). Furthermore, any features and functionalities disclosed herein with respect to an apparatus can also be used in a corresponding method. In other words, the methods disclosed herein can be supplemented by any of the features and functionalities described with respect to the apparatuses.

Also, any of the features and functionalities described herein can be implemented in hardware or in software, or using a combination of hardware and software, as will be described in the section “implementation alternatives”.

### Implementation Alternatives:

Depending on certain implementation requirements, embodiments of the invention can be implemented in hardware or in software. The implementation can be performed using a digital storage medium, for example a floppy disk, a DVD, a Blu-Ray, a CD, a ROM, a PROM, an EPROM, an EEPROM or a FLASH memory, having electronically readable control signals stored thereon, which cooperate (or are capable of cooperating) with a programmable computer system such that the respective method is performed. Therefore, the digital storage medium may be computer readable.

Some embodiments according to the invention comprise a data carrier having electronically readable control signals, which are capable of cooperating with a programmable computer system, such that one of the methods described herein is performed.

Generally, embodiments of the present invention can be implemented as a computer program product with a program code, the program code being operative for performing one of the methods when the computer program product runs on a computer. The program code may for example be stored on a machine readable carrier.

Other embodiments comprise the computer program for performing one of the methods described herein, stored on a machine readable carrier.

In other words, an embodiment of the inventive method is, therefore, a computer program having a program code for performing one of the methods described herein, when the computer program runs on a computer.

A further embodiment of the inventive methods is, therefore, a data carrier (or a digital storage medium, or a computer-readable medium) comprising, recorded thereon, the computer program for performing one of the methods described herein. The data carrier, the digital storage medium or the recorded medium are typically tangible and/or non-transitionary.

A further embodiment of the inventive method is, therefore, a data stream or a sequence of signals representing the computer program for performing one of the methods described herein. The data stream or the sequence of signals may for example be configured to be transferred via a data communication connection, for example via the Internet.

A further embodiment comprises a processing means, for example a computer, or a programmable logic device, configured to or adapted to perform one of the methods described herein.

A further embodiment comprises a computer having installed thereon the computer program for performing one of the methods described herein.

A further embodiment according to the invention comprises an apparatus or a system configured to transfer (for example, electronically or optically) a computer program for performing one of the methods described herein to a receiver. The receiver may, for example, be a computer, a mobile device, a memory device or the like. The apparatus or system may, for example, comprise a file server for transferring the computer program to the receiver.

In some embodiments, a programmable logic device (for example a field programmable gate array) may be used to perform some or all of the functionalities of the methods described herein. In some embodiments, a field programmable gate array may cooperate with a microprocessor in order to perform one of the methods described herein. Generally, the methods are performed by any hardware apparatus.

The apparatus described herein may be implemented using a hardware apparatus, or using a computer, or using a combination of a hardware apparatus and a computer.

The apparatus described herein, or any components of the apparatus described herein, may be implemented at least partially in hardware and/or in software.

The methods described herein may be performed using a hardware apparatus, or using a computer, or using a combination of a hardware apparatus and a computer.

The methods described herein, or any components of the apparatus described herein, may be performed at least partially by hardware and/or by software.

While this invention has been described in terms of several advantageous embodiments, there are alterations, permutations, and equivalents, which fall within the scope of this invention. It should also be noted that there are many alternative ways of implementing the methods and compositions of the present invention. It is therefore intended that the following appended claims be interpreted as including all such alterations, permutations, and equivalents as fall within the true spirit and scope of the present invention.

The description is now resumed with respect to the announced subsequently described embodiments/claims.

1. Decoder for decoding a digital time-varying signal from a data stream, configured to
decode the digital time-varying signal from the data stream in temporal blocks by decoding each of sample-wise-entropy-coded temporal blocks of the temporal blocks of the digital time-varying signal by sequentially determining a predetermined sample value for sample positions of the respective sample-wise-entropy-coded temporal block by
decoding a residual sample value for a current sample position of the respective sample-wise-entropy-coded temporal block from the data stream, and
correcting a prediction sample value for the current sample position using the residual sample value,
wherein in the decoding the residual sample value for the current sample position of the respective sample-wise-entropy-coded temporal block involves binary context-adaptively entropy decoding a first portion of a binarization of the residual sample value and decoding a remainder portion of the binarization from the data stream,
wherein the decoder is configured to
derive a context for decoding at least one bin of the first portion using the predetermined sample value of one or more previous sample positions of the respective sample-wise-entropy-coded temporal block.

2. Decoder of claim 1, configured to
derive a first context for decoding a first predetermined bin of the first portion using
a sum of absolute values of the predetermined sample value of preceding sample positions of the respective sample-wise-entropy-coded temporal block positioned within a template having a predetermined relative temporal position relative to the current sample position and use the first context for entropy decoding the at least one bin, and/or
a zeroness and/or a sign of the predetermined sample value of an immediately preceding sample position of the respective sample-wise-entropy-coded temporal block.

3. Decoder of claim 2, wherein
the first predetermined bin is a significance flag indicative of the residual sample value being zero or not.

4. Decoder of claim 1, configured to
derive a second context for decoding a sequence of greater-bins of the first portion, each of which being indicative of whether the residual sample value is greater than x+const with x being a rank of the respective greater-bin, depending one or more of
x−1, or x−1 clipped to a first maximum value, or
a sum of absolute values of the predetermined sample value of preceding sample positions of the respective sample-wise-entropy-coded temporal block positioned within a template having the predetermined relative temporal position relative to the current sample position and use the second context for entropy decoding the at least one bin, or a quantized and clipped version of the sum.

5. Decoder of claim 1, configured to
derive the prediction sample value for the current sample position using a template of K sample positions immediately preceding the current sample position along a sample order along which the predetermined sample value for the sample positions of the respective sample-wise-entropy-coded temporal block are sequentially decoded, by forming a weighted sum of the predetermined sample value of the respective sample-wise-entropy-coded temporal block at the K sample positions.

6. Decoder of claim 5 configured to
derive a second context for decoding a sequence of greater-bins of the first portion, each of which being indicative of whether the residual sample value is greater than x+const with x being a rank of the respective greater-bin, depending on
x−1, or x−1 clipped to a first maximum value, and
whether the current sample position is, reverse to the sample order, distanced by less than K sample positions from a previously decoded temporal block.

7. Decoder of claim 1 configured to, in decoding the remainder portion of the binarization from the data stream,
determine a Rice parameter by quantizing or thresholding an absolute sum measure over the predetermined sample value of all preceding sample positions of the respective sample-wise-entropy-coded temporal block, and
decode a Rice code using the Rice parameter.

8. Decoder of claim 7, wherein the Rice code comprises a unary code quotient portion, and the decoder is configured to decode bins of the unary code quotient portion by means of context-adaptive binary entropy decoding.

9. Decoder of claim 8, wherein the unary code quotient portion is a truncated unary code truncated so that a number of codewords of the truncated unary code is limited to a predefined maximal quotient value and wherein, if the unary code portion of the Rice code assumes a predetermined codeword associated with the predefined maximal quotient value, a fixed length remainder portion of the Rice coding is absent and the decoder is configured to, if the unary code portion of the Rice code does not assume the predetermined codeword associated with the predefined maximal quotient value, decode the fixed length remainder portion having a length corresponding to the Rice parameter.

10. Decoder of claim 9, wherein the decoder is configured to, if the unary code portion of the Rice code assumes the predetermined codeword associated with the predefined maximal quotient value, decode an exponential Golomb code as an extension of the Rice code.

11. Decoder of claim 1, configured to, in decoding each of sample-wise-entropy-coded temporal blocks of the temporal blocks of the digital time-varying signal,
predict the respective sample-wise-entropy-coded temporal blocks of the temporal blocks using a selected one out of a set of prediction modes to acquire a prediction signal, and
correcting, at each of the sample positions of the respective sample-wise-entropy-coded temporal block, the prediction signal using the predetermined sample value for the respective sample position of the respective sample-wise-entropy-coded temporal block.

12. Decoder for decoding a digital time-varying signal from a data stream, configured to
decode the digital time-varying signal from the data stream in temporal blocks by decoding each of coefficient-wise-entropy-coded temporal blocks of the temporal blocks of the digital time-varying signal by
deriving, from the data stream, a predetermined rank indicating that, among transform coefficients of the coefficient-wise-entropy-coded temporal blocks, those transform coefficients having, along a scan order defined among the transform coefficients, a rank greater than the predetermined rank are zero,
sequentially, reverse relative to the scan order, decoding the transform coefficients having a rank smaller than the predetermined rank,
subjecting the transform coefficients of the respective coefficient-wise-entropy-coded temporal block to a re-transformation to acquire a time-domain residual signal,
reconstructing the respective coefficient-wise-entropy-coded temporal block by correcting a prediction signal for the respective coefficient-wise-entropy-coded temporal block using the time-domain residual signal,
wherein
1) the decoder is configured to derive the predetermined rank from the data stream by
decoding a coarse rank index indexing one of several coarse rank positions along the scan order, and
decoding a fine rank offset pointing to the predetermined rank relative to the one coarse rank position, and/or
2) the decoder is configured to, in the sequentially, reverse relative to the scan order, decoding the transform coefficients having a rank smaller than the predetermined rank, decode a currently decoded transform coefficient of the respective coefficient-wise-entropy-coded temporal block by binary context-adaptively entropy decoding a first portion of a binarization of the currently decoded transform coefficient and decoding a remainder portion of the binarization from the data stream, with
deriving a context for decoding at least one bin of the first portion using one or more previously decoded transform coefficients of the respective coefficient-wise-entropy-coded temporal block.

13. Decoder of claim 12, configured to
derive the predetermined rank from the data stream by
decoding the fine rank offset using a fixed length code.

14. Decoder of claim 13, configured to
decoding the fixed length code from the data stream at a code rate of 1.

15. Decoder of claim 12, configured to
derive the predetermined rank from the data stream by
decoding the coarse rank index using a truncated unary code if the one coarse rank position falls onto one of X leading coarse rank positions in scan order, and using the truncated unary code for X followed by a truncated binary code for indexing the one coarse rank position out of subsequent coarse rank positions following the X leading coarse rank positions in scan order, if the one coarse rank position does not fall onto the X leading coarse rank positions in scan order.

16. Decoder of claim 12, configured to
in the sequentially, reverse relative to the scan order, decoding the transform coefficients having a rank smaller than the predetermined rank, decode the currently decoded transform coefficient of the respective coefficient-wise-entropy-coded temporal block with
deriving the context for decoding at least one bin of the first portion by quantizing or thresholding a sum measure over absolute values of previously decode transform coefficients within a template covering a predetermined number of rank positions prior to the currently decoded transform coefficient in scan order.

17. Decoder of claim 12, configured to
in the sequentially, reverse relative to the scan order, decoding the transform coefficients having a rank smaller than the predetermined rank, decode the currently decoded transform coefficient of the respective coefficient-wise-entropy-coded temporal block with
derive a second context for decoding a sequence of greater-bins of the first portion, each of which being indicative of whether the residual sample value is greater than x+const with x being a rank of the respective greater-bin, depending on
a quantized version of the rank of the currently decoded transform coefficient.

18. Decoder of claim 12, configured to decode the transform coefficients using a binarization comprising a significance bin and, in decoding the transform coefficient whose position in scan order is equal to the predetermined rank, infer that this significance flag indicates non-zeroness.

19. Decoder of claim 12, configured to decode the transform coefficients using a binarization comprising a significance bin and, in decoding the transform coefficient whose position in scan order is equal to the predetermined rank, decode the significance bin if the predetermined rank falls onto a last rank in the scan order, and infer that this significance flag indicates non-zeroness if the predetermined rank does not fall onto the last rank in the scan order.

20. Decoder of claim 12, configured to, in the sequentially, reverse relative to the scan order, decoding the transform coefficients having a rank smaller than the predetermined rank, decode the currently decoded transform coefficient of the respective coefficient-wise-entropy-coded temporal block by deriving a context for decoding at least one bin of the first portion depending a rank of the currently decoded transform coefficient.

21. Encoder for encoding a digital time-varying signal into a data stream, configured to
encode the digital time-varying signal into the data stream in temporal blocks by encoding each of sample-wise-entropy-coded temporal blocks of the temporal blocks of the digital time-varying signal by sequentially determining predetermined sample value for sample positions of the respective sample-wise-entropy-coded temporal block by
encoding a residual sample value for a current sample position of the respective sample-wise-entropy-coded temporal block into the data stream, the residual sample value being for correcting a prediction sample value for the current sample position using the residual sample value,
wherein in the encoding the residual sample value for the current sample position of the respective sample-wise-entropy-coded temporal block involves binary context-adaptively entropy encoding a first portion of a binarization of the residual sample value and encoding a remainder portion of the binarization into the data stream,
wherein the encoder is configured to
derive a context for encoding at least one bin of the first portion using the predetermined sample value of one or more previous sample positions of the respective sample-wise-entropy-coded temporal block.

22. Encoder of claim 21, configured to
derive a first context for encoding a first predetermined bin of the first portion using
a sum of absolute values of the predetermined sample value of preceding sample positions of the respective sample-wise-entropy-coded temporal block positioned within a template having a predetermined relative temporal position relative to the current sample position and use the first context for entropy encoding the at least one bin, and/or
a zeroness and/or a sign of the predetermined sample value of an immediately preceding sample position of the respective sample-wise-entropy-coded temporal block.

23. Encoder of claim 22, wherein
the first predetermined bin is a significance flag indicative of the residual sample value being zero or not.

24. Encoder of claim 21, configured to
derive a second context for encoding a sequence of greater-bins of the first portion, each of which being indicative of whether the residual sample value is greater than x+const with x being a rank of the respective greater-bin, depending one or more of
x−1, or x−1 clipped to a first maximum value, or
a sum of absolute values of the predetermined sample value of preceding sample positions of the respective sample-wise-entropy-coded temporal block positioned within a template having the predetermined relative temporal position relative to the current sample position and use the second context for entropy encoding the at least one bin, or a quantized and clipped version of the sum.

25. Encoder of claim 21, configured to
derive the prediction sample value for the current sample position using a template of K sample positions immediately preceding the current sample position along a sample order along which the predetermined sample value for the sample positions of the respective sample-wise-entropy-coded temporal block are sequentially encoded, by forming a weighted sum of the predetermined sample value of the respective sample-wise-entropy-coded temporal block at the K sample positions.

26. Encoder of claim 25 configured to
derive a second context for encoding a sequence of greater-bins of the first portion, each of which being indicative of whether the residual sample value is greater than x+const with x being a rank of the respective greater-bin, depending on
x−1, or x−1 clipped to a first maximum value, and
whether the current sample position is, reverse to the sample order, distanced by less than K sample positions from a previously encoded temporal block.

27. Encoder of claim 21 configured to, in encoding the remainder portion of the binarization into the data stream,
determine a Rice parameter by quantizing or thresholding an absolute sum measure over the predetermined sample value of all preceding sample positions of the respective sample-wise-entropy-coded temporal block, and
encode a Rice code using the Rice parameter.

28. Encoder of claim 27, wherein the Rice code comprises a unary code quotient portion, and the encoder is configured to encode bins of the unary code quotient portion by means of context-adaptive binary entropy encoding.

29. Encoder of claim 28, wherein the unary code quotient portion is a truncated unary code truncated so that a number of codewords of the truncated unary code is limited to a predefined maximal quotient value and wherein, if the unary code portion of the Rice code assumes a predetermined codeword associated with the predefined maximal quotient value, a fixed length remainder portion of the Rice coding is absent and the encoder is configured to, if the unary code portion of the Rice code does not assume the predetermined codeword associated with the predefined maximal quotient value, encode the fixed length remainder portion having a length corresponding to the Rice parameter.

30. Encoder of claim 29, wherein the encoder is configured to, if the unary code portion of the Rice code assumes the predetermined codeword associated with the predefined maximal quotient value, encode an exponential Golomb code as an extension of the Rice code.

31. Encoder of claim 21, configured to, in encoding each of sample-wise-entropy-coded temporal blocks of the temporal blocks of the digital time-varying signal,
predict the respective sample-wise-entropy-coded temporal blocks of the temporal blocks using a selected one out of a set of prediction modes to acquire a prediction signal, so that, at each of the sample positions of the respective sample-wise-entropy-coded temporal block, the prediction signal is correctable using the predetermined sample value for the respective sample position of the respective sample-wise-entropy-coded temporal block.

32. Encoder for encoding a digital time-varying signal into a data stream, configured to
encode the digital time-varying signal into the data stream in temporal blocks by encoding each of coefficient-wise-entropy-coded temporal blocks of the temporal blocks of the digital time-varying signal by
subjecting a time-domain residual signal of the respective coefficient-wise-entropy-coded temporal block, ought to allow for reconstructing the respective coefficient-wise-entropy-coded temporal block by correcting a prediction signal for the respective coefficient-wise-entropy-coded temporal block using the time-domain residual signal, to a transformation to acquire the transform coefficients,
signaling in the data stream, a predetermined rank indicating that, among the transform coefficients of the coefficient-wise-entropy-coded temporal blocks, those transform coefficients having, along a scan order defined among the transform coefficients, a rank greater than the predetermined rank are zero,
sequentially, reverse relative to the scan order, encoding the transform coefficients having a rank smaller than the predetermined rank,
wherein
1) the encoder is configured to encode the predetermined rank into the data stream by
encoding a coarse rank index indexing one of several coarse rank positions along the scan order, and
encoding a fine rank offset pointing to the predetermined rank relative to the one coarse rank position, and/or
2) the encoder is configured to, in the sequentially, reverse relative to the scan order, encoding the transform coefficients having a rank smaller than the predetermined rank, encode a currently encoded transform coefficient of the respective coefficient-wise-entropy-coded temporal block by binary context-adaptively entropy encoding a first portion of a binarization of the currently decoded transform coefficient and encoding a remainder portion of the binarization into the data stream, with
deriving a context for encoding at least one bin of the first portion using one or more previously encoded transform coefficients of the respective coefficient-wise-entropy-coded temporal block.

33. Encoder of claim 32, configured to
encode the predetermined rank into the data stream by
encoding the fine rank offset using a fixed length code.

34. Encoder of claim 33, configured to
encoding the fixed length code into the data stream at a code rate of 1.

35. Encoder of claim 32, configured to
encode the predetermined rank into the data stream by
encoding the coarse rank index using a truncated unary code if the one coarse rank position falls onto one of X leading coarse rank positions in scan order, and using the truncated unary code for X followed by a truncated binary code for indexing the one coarse rank position out of subsequent coarse rank positions following the X leading coarse rank positions in scan order, if the one coarse rank position does not fall onto the X leading coarse rank positions in scan order.

36. Encoder of claim 32, configured to
in the sequentially, reverse relative to the scan order, encoding the transform coefficients having a rank smaller than the predetermined rank, encode the currently encoded transform coefficient of the respective coefficient-wise-entropy-coded temporal block with
deriving the context for encoding at least one bin of the first portion by quantizing or thresholding a sum measure over absolute values of previously encode transform coefficients within a template covering a predetermined number of rank positions prior to the currently encoded transform coefficient in scan order.

37. Encoder of claim 32, configured to
in the sequentially, reverse relative to the scan order, encoding the transform coefficients having a rank smaller than the predetermined rank, encode the currently encoded transform coefficient of the respective coefficient-wise-entropy-coded temporal block with
derive a second context for encoding a sequence of greater-bins of the first portion, each of which being indicative of whether the residual sample value is greater than x+const with x being a rank of the respective greater-bin, depending on
a quantized version of the rank of the currently encoded transform coefficient.

38. Encoder of claim 32, configured to encode the transform coefficients using a binarization comprising a significance bin and, in encoding the transform coefficient whose position in scan order is equal to the predetermined rank, infer that this significance flag indicates non-zeroness.

39. Encoder of claim 32, configured to encode the transform coefficients using a binarization comprising a significance bin and, in encoding the transform coefficient whose position in scan order is equal to the predetermined rank, encode the significance bin if the predetermined rank falls onto a last rank in the scan order, and infer that this significance flag indicates non-zeroness if the predetermined rank does not fall onto the last rank in the scan order.

40. Encoder of claim 32, configured to, in the sequentially, reverse relative to the scan order, encoding the transform coefficients having a rank smaller than the predetermined rank, encode the currently encoded transform coefficient of the respective coefficient-wise-entropy-coded temporal block by deriving a context for encoding at least one bin of the first portion depending on a rank of the currently encoded transform coefficient.

41. Method for decoding for decoding a digital time-varying signal from a data stream, the method comprising
decoding the digital time-varying signal from the data stream in temporal blocks by decoding each of sample-wise-entropy-coded temporal blocks of the temporal blocks of the digital time-varying signal by sequentially determining a predetermined sample value for sample positions of the respective sample-wise-entropy-coded temporal block by
decoding a residual sample value for a current sample position of the respective sample-wise-entropy-coded temporal block from the data stream, and
correcting a prediction sample value for the current sample position using the residual sample value,
wherein in the decoding the residual sample value for the current sample position of the respective sample-wise-entropy-coded temporal block involves binary context-adaptively entropy decoding a first portion of a binarization of the residual sample value and decoding a remainder portion of the binarization from the data stream,
wherein the method comprises
deriving a context for decoding at least one bin of the first portion using the predetermined sample value of one or more previous sample positions of the respective sample-wise-entropy-coded temporal block.

42. Method for decoding a digital time-varying signal from a data stream, comprising
decoding the digital time-varying signal from the data stream in temporal blocks by decoding each of coefficient-wise-entropy-coded temporal blocks of the temporal blocks of the digital time-varying signal by
deriving, from the data stream, a predetermined rank indicating that, among transform coefficients of the coefficient-wise-entropy-coded temporal blocks, those transform coefficients having, along a scan order defined among the transform coefficients, a rank greater than the predetermined rank are zero,
sequentially, reverse relative to the scan order, decoding the transform coefficients having a rank smaller than the predetermined rank,
subjecting the transform coefficients of the respective coefficient-wise-entropy-coded temporal block to a re-transformation to acquire a time-domain residual signal,
reconstructing the respective coefficient-wise-entropy-coded temporal block by correcting a prediction signal for the respective coefficient-wise-entropy-coded temporal block using the time-domain residual signal,
wherein
1) the method comprises deriving the predetermined rank from the data stream by
decoding a coarse rank index indexing one of several coarse rank positions along the scan order, and
decoding a fine rank offset pointing to the predetermined rank relative to the one coarse rank position, and/or
2) the comprises, in the sequentially, reverse relative to the scan order, decoding the transform coefficients having a rank smaller than the predetermined rank, decoding a currently decoded transform coefficient of the respective coefficient-wise-entropy-coded temporal block by binary context-adaptively entropy decoding a first portion of a binarization of the currently decoded transform coefficient and decoding a remainder portion of the binarization from the data stream, with
deriving a context for decoding at least one bin of the first portion using one or more previously decoded transform coefficients of the respective coefficient-wise-entropy-coded temporal block.

43. Method for encoding a digital time-varying signal into a data stream, the method comprising
encoding the digital time-varying signal into the data stream in temporal blocks by encoding each of sample-wise-entropy-coded temporal blocks of the temporal blocks of the digital time-varying signal by sequentially determining predetermined sample value for sample positions of the respective sample-wise-entropy-coded temporal block by
encoding a residual sample value for a current sample position of the respective sample-wise-entropy-coded temporal block into the data stream, the residual sample value being for correcting a prediction sample value for the current sample position using the residual sample value,
wherein in the encoding the residual sample value for the current sample position of the respective sample-wise-entropy-coded temporal block involves binary context-adaptively entropy encoding a first portion of a binarization of the residual sample value and encoding a remainder portion of the binarization into the data stream,
wherein the method comprises
deriving a context for encoding at least one bin of the first portion using the predetermined sample value of one or more previous sample positions of the respective sample-wise-entropy-coded temporal block.

44. Method for encoding a digital time-varying signal into a data stream, the method comprising
encoding the digital time-varying signal into the data stream in temporal blocks by encoding each of coefficient-wise-entropy-coded temporal blocks of the temporal blocks of the digital time-varying signal by
subjecting a time-domain residual signal of the respective coefficient-wise-entropy-coded temporal block, ought to allow for reconstructing the respective coefficient-wise-entropy-coded temporal block by correcting a prediction signal for the respective coefficient-wise-entropy-coded temporal block using the time-domain residual signal, to a transformation to acquire the transform coefficients,
signaling in the data stream, a predetermined rank indicating that, among the transform coefficients of the coefficient-wise-entropy-coded temporal blocks, those transform coefficients having, along a scan order defined among the transform coefficients, a rank greater than the predetermined rank are zero,
sequentially, reverse relative to the scan order, encoding the transform coefficients having a rank smaller than the predetermined rank,
wherein
1) the method comprises encoding the predetermined rank into the data stream by
encoding a coarse rank index indexing one of several coarse rank positions along the scan order, and
encoding a fine rank offset pointing to the predetermined rank relative to the one coarse rank position, and/or
2) the method comprises, in the sequentially, reverse relative to the scan order, encoding the transform coefficients having a rank smaller than the predetermined rank, encoding a currently encoded transform coefficient of the respective coefficient-wise-entropy-coded temporal block by binary context-adaptively entropy encoding a first portion of a binarization of the currently decoded transform coefficient and encoding a remainder portion of the binarization into the data stream, with
deriving a context for encoding at least one bin of the first portion using one or more previously encoded transform coefficients of the respective coefficient-wise-entropy-coded temporal block.

45. Data stream encoded using the method according to claim 43.

46. Data stream encoded using the method according to claim 44.

47. A non-transitory digital storage medium having a computer program stored thereon to perform the method of claim 41 to 44 when said computer program is run by a computer.
